(19) United States
(12) Patent Application Publication
(10) Pub. No.: US 2010/0186794 A1
(43) Pub. Date: Jul. 29, 2010

(54) SOLAR THERMOELECTRIC AND THERMAL COGENERATION

(75) Inventors: Gang Chen, Carlisle, MA (US); Zhifeng Ren, Newton, MA (US)

Correspondence Address: FOLEY AND LARDNER LLP;SUITE 500, 3000 K STREET NW, WASHINGTON, DC, 20007, US

(73) Assignee: GMZ Energy ,Inc.

(21) Appl. No.: 12/451,614

(22) PCT Filed: May 20, 2008
(86) PCT No.: PCT/US2008/006441

§ 371 Date: Mar. 12, 2010

Related U.S. Application Data
(60) Provisional application No. 60/939,126, filed on May 21, 2007.
(60) Provisional application No. 61/071,204, filed on Apr. 17, 2008.

(51) Int. Cl. H01L 35/00

(52) U.S. Cl. 136/206

(57) ABSTRACT

An energy generation method includes receiving solar radiation at a solar absorber, providing heat from the solar absorber to a hot side of a set of thermoelectric converters, generating electricity from the set of thermoelectric converters, and providing heat from a cold side of the set of thermoelectric converters to a fluid being provided into a solar fluid heating system or a solar thermal to electrical conversion plant. A system for carrying out the method includes at least one thermoelectric device and a solar fluid heating system or a solar thermal to electrical conversion plant

### CROSS-REFERENCE TO RELATED PATENT APPLICATIONS

The present application claims the benefit of a U.S. Provisional Patent Application Ser. No. 60/939,126, filed May 21, 2007 and of U.S. Provisional Patent Application Ser. No. 61/071,204, filed Apr. 17, 2008. The entire contents of these provisional applications are hereby incorporated by reference herein.

### FIELD OF THE INVENTION

The present invention relates generally to methods and devices for the conversion of solar energy. Specifically, the present invention relates to methods and devices that combine solar thermoelectric conversion with solar thermal conversion.

### BACKGROUND OF THE INVENTION

Solar energy converters include solar electric, solar fuel, and solar thermal converters. Solar electric converters convert solar energy into electrical energy directly, with solar photovoltaic (PV) cells, or indirectly, with solar thermal to electric converters Solar fuel converters extract fuels from a solution using electrolysis, where the electrical energy driving the electrolysis step comes directly from PV cells. Solar thermal converters convert solar energy into thermal energy or heat.

Both PV cells and solar thermal converters are used residentially, with hot water systems taking the larger market share. Some countries have focused on roof-top PV cells, while other countries have widespread use of roof-top hot-water systems.

In addition to functioning strictly as hot water systems, solar thermal converters have been used to generate electrical energy by driving mechanical heat engines with steam generated from the solar thermal converter. In a solar thermal converter, one or more fluid conduits are provided in direct thermal contact with a solar radiation absorbing surface. The surface absorbs solar radiation and transfers heat to the conduits. The transferred heat raises the temperature of the fluid, such as oil, liquid salt or water flowing through the conduit. The heated fluid is then used in a power generator, such as a steam driven power generator to generate electricity. The term “fluid”, as used herein includes both liquid or gases.

In contrast, thermoelectric power generation relies on the Seebeck effect in solid materials to convert thermal energy into electricity. The theoretical energy conversion efficiency ηₜₑ of a thermoelectric device operating between a hot-side temperature Tₕ and a cold-side temperature T_{c} is given by:

$${n}_{te} = ( 1 - \frac{{T}_{c}}{{T}_{h}} ) \frac{\sqrt{1 + ZT} - 1}{\sqrt{1 + ZT} + {T}_{c} / {T}_{h}} \qquad ( 1 )$$

where the first factor, in parenthesis, is the Carnot efficiency and the second factor, the fractional component, is determined by the thermoelectric figure of merit Z and the average temperature T=0.5(Tₕ+Tₑ) of the thermoelectric materials.

The thermoelectric figure of merit Z is related to the Seebeck coefficient S of the thermoelectric material by the following equation:

Z=S²σ/k (2)

where σ is the electrical conductivity and k is the thermal conductivity of the thermoelectric material.

Thermoelectric devices operating between Tₕ=500 K and T_{c}=300 K, with a dimensionless figure of merit ZT between 1-2, can have an efficiencies of 9-14%. Increasing the temperature difference between the hot-side and cold-side to Tₕ=1000 K and T_{c}=300 K improves efficiencies of the thermoelectric device to 17-25%. In the past, the maximum ZT of thermoelectric materials has been limited to about 1, yielding thermoelectric power generators with low efficiencies. As an example, one prior art system uses Si₈₀Ge₂₀ alloys as a thermoelectric material in thermoelectric generators and radioisotopes as a heat source, with the system operating at a maximum temperature of 900° C. and a thermal energy to electricity energy conversion efficiency of 6%.

More recently, with the introduction of new thermoelectric materials, researchers have achieved thermal energy to electrical energy conversion efficiencies of 12-14%. A large increase in ZT has been reported using Bi₂Te₃/Sb₂Te₃ superlattices and PbTe/PbSe superlattices, and using nanostructured bulk materials. A ZT value as high as 3.5 has been reported in PbTe/PbSe superlattices at 300° C.

### SUMMARY OF THE INVENTION

An energy generation method includes receiving solar radiation at a solar absorber, providing heat from the solar absorber to a hot side of a set of thermoelectric converters, generating electricity from the set of thermoelectric converters, and providing heat from a cold side of the set of thermoelectric converters to a fluid being provided into a solar fluid heating system or a solar thermal to electrical conversion plant. A system for carrying out the method includes at least one thermoelectric device and a solar fluid heating system or a solar thermal to electrical conversion plant.

### BRIEF DESCRIPTION OF THE DRAWINGS

The foregoing and other objects, features, and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating principles of the invention.

FIG. 1 is a side-view depiction of a flat-panel configuration of a solar-electrical generator module, consistent with some embodiments of the present invention.

FIG. 2 depicts a graph of the reflectivity of different polished copper surfaces as a function of wavelength, allowing deduction of the emissivity, consistent with some embodiments of the present invention.

FIG. 3 is a side-view depiction of a flat-panel configuration of a solar-electrical generator module with one p-type leg and one n-type leg, consistent with some embodiments of the present invention.

FIG. 4 is a side-view depiction of several flat-panel modules enclosed in an isolated environment, consistent with some embodiments of the present invention.

FIG. 5A is a side-view depiction of a solar-electrical generator using a lens as a solar concentrator, consistent with some embodiments of the present invention.

FIG. 5B is a side-view depiction of a solar-electrical generator using two reflective structures as a solar concentrator, consistent with some embodiments of the present invention.

FIG. 5C is a side-view depiction of a solar-electrical generator using a transmissive lens as a solar concentrator that contacts a solar capture structure, consistent with some embodiments of the present invention.

FIG. 6A is a side-view depiction of a solar-electrical generator utilizing a solar concentrator and a thermoelectric converter in a horizontal position, consistent with some embodiments of the present invention.

FIG. 6B is a side-view depiction of a solar-electrical generator utilizing a solar concentrator and two thermoelectric converters in a horizontal position stacked on top of each other, consistent with some embodiments of the present invention.

FIG. 6C is a side-view depiction of a solar-electrical generator utilizing a solar concentrator in a mushroom shape and a thermoelectric converter in a horizontal position, consistent with some embodiments of the present invention.

FIG. 7 is a side-view depiction of a solar-electrical generator utilizing a plurality of reflective surfaces arranged in a trough design as a plurality of solar concentrators, consistent with some embodiments of the present invention.

FIG. 8A is a perspective view depiction of a solar-electrical generator utilizing a plurality of lens structures as a plurality of solar concentrators, consistent with some embodiments of the present invention.

FIG. 8B is a side view depiction of the solar-electrical generator shown in FIG. 8A.

FIG. 9 is a side-view depiction of a solar-electrical generator utilizing a plurality of lens structures as a plurality of solar concentrators and a single solar thermoelectric generator having grouped converters, consistent with some embodiments of the present invention.

FIG. 10A is a side-view depiction of a solar-electrical generator using a flat Fresnel lens as a solar concentrator and a barrier structure enclosing a thermoelectric converter in an isolated environment, consistent with some embodiments of the present invention.

FIG. 10B is a side-view depiction of a solar-electrical generator using a curved Fresnel lens as a solar concentrator and a barrier structure enclosing a thermoelectric converter in an isolated environment, consistent with some embodiments of the present invention.

FIG. 10C is a side-view depiction of a solar-electrical generator using two reflective surfaces to concentrate solar radiation onto a barrier structure enclosing a thermoelectric converter in an isolated environment, consistent with some embodiments of the present invention.

FIG. 11 is a side-view depiction of a solar-electrical generator using a parabolic reflective surface to concentrate solar radiation onto a barrier structure enclosing a converter coupled to a capture structure having a protruding element, consistent with some embodiments of the present invention.

FIG. 12 is a side-view depiction of a support structure coupled to a fluid-based heat transfer system for removing heat from the support structure, consistent with some embodiments of the present invention.

FIG. 13A provides a schematic of a prototype solar-electrical generator, consistent with some embodiments of the present invention.

FIG. 13B provides a graph of power versus load resistance tested in the prototype solar-electrical generator represented in FIG. 13A.

FIG. 13C provides a graph of efficiency versus load resistance tested consistent with the data shown in FIG. 13B.

FIGS. 14A-14D provide three dimensional views of a solar thermal-thermoelectric (STTE) converter elements in accordance with embodiments of the present invention.

FIGS. 15 and 16 are plots of ZT values versus temperature for several thermoelectric converter materials vs. temperature.

FIGS. 17A and 17B are schematic depictions of two possible nanostructure thermoelectric materials composites for thermoelectric materials.

FIG. 18A shows TEM images for Bi₂Te₃ and Bi₂Se₃ nanoparticles.

FIG. 18B shows TEM images for compacted samples from Bi₂Te₃ based alloy nanopowder.

FIG. 19A-19E illustrate temperature dependence of electrical conductivity, Seebeck coefficient, power factor, thermal conductivity and ZT value, respectively, of SiGe nanocomposite materials.

FIGS. 20A-20C are schematic three dimensional views of 2D and 3D solar energy flux concentrators.

FIG. 21A illustrates a series of trough concentrators and FIG. 21B illustrates a fluid conduit used in power plants populated by solar thermo-thermoelectric converters.

FIG. 22 provides a side cross sectional view of an individual solar thermo-thermoelectric converter cell.

FIGS. 23A-C illustrate ZT value dependence of efficiency, thermal concentration ratio and hot size temperature for thermoelectric devices according to embodiments of the invention.

FIG. 24 is a plot of expected electrical and water heating efficiencies as a function of ZT value for a hot water heating system of an embodiment of the invention.

FIG. 25 is a plot of expected electrical and heating efficiencies as a function of ZT value for a system of an embodiment of the invention.

### DETAILED DESCRIPTION OF THE PREFERRED EMBODIMENTS

The present inventors realized that solar energy conversion system efficiency would be improved if the solar thermoelectric device was integrated with a solar thermal conversion device, such as a solar fluid heating device or a solar thermal to electrical plant. A solar thermal to electrical conversion plant (which can be referred to simply as a “solar thermal plant”) includes but is not limited to Rankine based and Stirling based plants, and includes trough, tower, and dish shaped plants, as will be described below. Such a system co-generates solar electrical energy and solar thermal energy. Specifically, if the solar thermal conversion device is a solar fluid heating system, such as a solar hot water heating system, then the system can provide cogeneration of electricity using the solar thermoelectric device, and hot water for a facility, such as a building, using the solar hot water system.

In one embodiment of the invention, the inventors also realized that in a combination system that includes both the thermoelectric device and the solar fluid heating system, the fluid conduit should be physically separated and thermally decoupled from the solar radiation absorbing surface by the poorly thermally conducting thermoelectric material legs or posts, so that a proper temperature difference can be created across the thermoelectric legs or posts, and consequently, between the solar absorbing surface and the fluid conduits. This system configuration is opposite from the prior art system containing only the solar fluid heating device in which the fluid conduit is placed in thermal contact with the solar radiation absorbing surface for optimum transfer of the heat from the absorbing surface to the fluid.

The thermoelectric device generates electricity due to a temperature difference between its cold side and its hot side which is in thermal contact and optionally in physical contact with the absorbing surface. As used herein, the terms thermal contact or thermal integration between two surfaces means that heat is efficiently transferred between the surfaces either because the surfaces are in direct physical contact or are not in direct contact but are connected by a thermally conductive material, such as metal, etc.

The inventors realized that if the fluid conduit of the solar thermal conversion device is also placed in thermal contact with the solar absorber (also referred to as a solar absorbing surface), then the fluid conduit will act as a heat sink. This will significantly reduce the temperature difference between the hot and cold sides of the thermoelectric device and would thus significantly decrease the efficiency of the thermoelectric device.

In contrast, if the fluid conduit is placed in thermal contact with the cold side of the thermoelectric device, then the fluid conduit will act as a heat sink and increase the temperature difference between the hot and cold sides of the thermoelectric device and thus improve the efficiency of the thermoelectric device. Since the thermoelectric converters (e.g., semiconductor legs or posts) of the thermoelectric device are poor thermal converters, the fluid conduit is not in thermal contact (i.e., not thermally integrated) with the solar absorber surface. Thus, the fluid conduit does not act as a heat sink for the solar absorber surface and does not interfere with the operation of the thermoelectric device.

Furthermore, the cold side of the thermoelectric device is still sufficiently warm (i.e., is above room temperature) to heat the fluid, such as water or oil, inside the fluid conduit to a desired temperature. For example, for a hot water heating system, the cold side of the thermoelectric device may be maintained at a temperature of about 50 to about 150° C., such as for example less than 100° C., preferably 30 to 70° C., which is sufficiently high to heat water to about 40 to about 150° C. for home, commercial or industrial use. Thus, the water heated by the cold side of the thermoelectric device is provided from the fluid conduit into the facility as hot water for various uses, such as hot water for showers or sinks, hot water or steam for use in radiators for room heating, etc. Alternatively, if the fluid, such as oil or salt is sufficiently heated, then it may be used in a thermal power plant to generate electricity. For example, the oil or salt may be heated above its boiling point. Alternatively, the oil or salt may be heated below its boiling point, but to a sufficiently high temperature so that it is used to heat water into steam, which is feed into steam turbine to generate electricity.

An optional solar energy flux collector and/or concentrator may also be provided above the solar absorber to collect and/or concentrate solar energy. Imaging and non-imaging optical methods that concentrate the incident solar energy flux may be used to collect and concentrate the solar energy flux to generate a higher solar energy flux density. This method of increasing energy flux is termed optical concentration. The hot side temperature depends on optical and thermal concentration ratio, as will be described in more detail below.

An optional selective surface passes solar energy in the visible (V) and ultra-violet (UV) spectra to a solar absorber (i.e., a solar absorbing surface). The solar absorber converts the solar radiation to thermal energy (i.e., heat). The selective surface retains heat in the solar absorber by limiting infrared radiation. An optional set of conduits with narrowing cross-sections conduct the thermal energy stored in the solar absorber to a set of thermoelectric converters (such as a set of alternating p-type and n-type semiconductor legs or posts), concentrating the absorbed thermal energy to the thermoelectric legs. With respect to the term “narrowing cross sections”, it should be noted that in a flat panel concentrator, preferably there is no physical narrowing of the thickness of the absorber. However, heat transfers to the thermoelectric legs in a nearly concentric fashion, and hence heat transfer area is actually changing. In other configurations the narrowing cross section may comprise a physically narrowing cross-section. Thus, the converters are in thermal contact with the solar absorber. The thermal energy concentration via heat conduction is termed thermal concentration. The resulting thermal energy flux density channeled through the set of thermoelectric converters, is determined by the cross-section, spacing, and length of the thermoelectric converters.

The energy flux flowing into thermoelectric devices can be increased via a combination of the optical concentration and thermal concentration, depending on the desirable hot and cold side temperature of the thermoelectric legs, on the properties of selective absorbers.

The thermoelectric converters convert a portion of the stored thermal energy into electrical energy. The thermoelectric converters themselves can be made from a variety of bulk materials and/or nanostructures. The converters preferably comprise a plural sets of two converter elements—one p-type and one n-type semiconductor converter post or leg which are electrically connected to form a p-n junction. The thermoelectric converter materials can comprise, but are not limited to, one of: Bi₂Te₃: Bi₂Te₃₋ₓSeₓ (n-type)/BiₓSe₂₋ₓTe₃ (p-type), SiGe (e.g., Si₈₀Ge₂₀) PbTe, skutterudites, Zn₃Sb₄, AgPbₘSbTe₂₊ₘ, Bi₂Te₃/Sb₂Te₃ quantum dot superlattices (QDSLs), PbTe/PbSeTe QDSLs, PbAgTe, and combinations thereof. The materials may comprise compacted nanoparticles or nanoparticles embedded in a bulk matrix material.

Optionally, a base comprising heat sink material is located between the cold side of the thermoelectric converters of the thermoelectric device and the fluid conduit. The base may comprise a metal or other highly thermally conductive material to provide a thermal contact between the thermoelectric converters and the fluid pipe. Heat associated with unconverted thermal energy conducts from the cold side of the thermoelectric device though the base to the fluid conduit. An optional heat exchanger may be located in the base. The fluid from the fluid conduit passes through the heat exchanger to receive heat from the thermoelectric device. The heat exchanger may comprise thermally conducting plates, a set of thermally conducting pipes, heat pipes, or combinations thereof. The resulting heated fluid, such as water and/or steam, is made available for residential, commercial or other use. If desired, the fluid may be circulated using one or more of driving with an impeller, pumping, siphoning, diffusing, and combinations thereof.

Thus, the system of the embodiments of the invention provides a higher efficiency using a combination of solar thermoelectric energy conversion and mechanical based solar thermal to electrical energy conversion, or solar fluid heating. More generally, a thermoelectric and thermal energy cogeneration method includes steps for receiving and optionally concentrating solar radiation on a solar absorber to heat the absorber, providing thermal energy (i.e., heat) from the absorber to a set of thermoelectric converters, converting a portion of the thermal energy to an electrical energy with the set of thermoelectric converters, providing an unconverted portion of the thermal energy to a displaceable medium, such a water or another fluid, and providing the displaceable medium for subsequent use.

It should be appreciated that the particular implementations shown and described herein are examples of the present invention and are not intended to otherwise limit the scope of the present invention in any way. Further, the techniques are suitable for applications in solar thermoelectric energy and solar thermal energy cogeneration, manufacturing and power plant thermal to electric energy and thermal energy cogeneration, or any other similar applications, particularly applications which presently waste or leave unconverted solar or thermal energy sources.

The thermal efficiency of a solar thermal converter ranges between approximately 50-70%, depending on the operation temperature. The efficiency of a thermoelectric converter is lower. Solar thermoelectric efficiency can be divided into the product of the two terms:

nₑ=nₛₜ(Tₛ,Tₕ)nₜₑ(Tₕ,T_{c}) (3)

The first term reflects the efficiency of solar to thermal energy conversion, converting photons with a characteristic temperature equal to that at the surface of the sun Tₛ, to phonons, or thermal energy, raising the temperature of the hot-side of the solar thermoelectric device to Tₕ. The second term represents the efficiency of the thermoelectric elements generating electrical energy from thermal energy, given a hot-side temperature and cold-side temperature of Tₕ and T_{c}, respectively. As shown in Eq. (1), this latter term depends on the ZT of the thermoelectric materials.

The efficiency ηₛₜ is a function of several heat loss mechanisms, including thermal radiation, convection, and conduction losses from the surfaces of the solar absorber and the thermoelectric elements. The above described solar thermoelectric energy conversion provides optimization of both ηₛₜ and ηₜₑ, and design of a device for cogeneration of thermoelectric energy and thermal energy, or more specifically, the cogeneration of solar thermoelectric energy and solar thermal energy, and addresses the inefficiencies in both conversion processes to improve the solar thermoelectric and solar thermal energy cogeneration.

The temperature difference, ΔT, across the thermoelectric legs needed for power generation is related to the heat flux through the legs, \dot{q}, by the following:

\dot{q}=kΔT/d (4)

where d is the length of thermoelectric legs and k is the thermal conductivity of thermoelectric materials. For a steady-state system, the heat flux \dot{q} is a constant. The average solar flux at the surface of the earth is approximately 1000 W/m². Using this value, and a typical thermoelectric converter constants of k=1 W/mK and d=1 mm result in a temperature difference of ΔT=1° C. A temperature difference this small generates a small amount of electrical energy from the thermoelectric converters. To increase the temperature difference, the heat flux flowing through the thermoelectric device should be increased above the solar flux. In solar thermoelectrics, this can be done by two ways. One way is to optically concentrate the incident solar radiation before it is absorbed and converted into heat, which will be called optical concentration, and the other is concentrate heat via heat conduction, after the solar flux is absorbed. The later will be called thermal concentration. A combination of the two methods can be used depending on applications.

### Thermal Concentrator Configurations

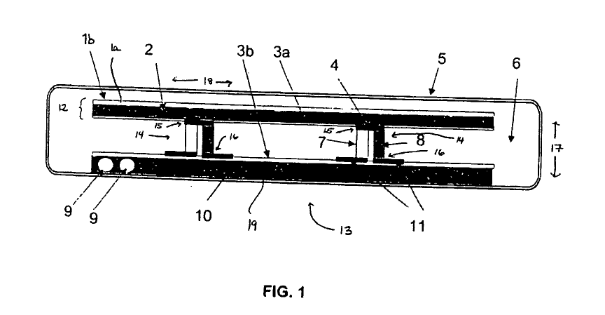

Thermal concentration uses different ratio of solar absorber area to the cross-sectional area of thermoelectric legs. FIG. 1 illustrates the thermoelectric device 13 which will be referred to more generally as solar-electrical generator 13 according to some embodiments of the invention. The generator 13 includes a solar absorber, which will be referred to as a radiation capture structure 12, coupled to one or more pairs of thermoelectric converters 14. The capture structure 12 includes a radiation-absorbing layer 1a that, in turn, includes a front surface 1b that is adapted for exposure to solar radiation, either directly or via a concentrator. Although in this example the front surface 1b is substantially flat, in other examples the layer 1a can be curved. Further, although the radiation-absorbing layer 1a is shown in this example as continuous, in other cases, it can be formed as a plurality of disjoint segments. The solar radiation impinged on the front surface 1b can generate heat in the capture structure 12, which can be transferred to one end 15 of each of the thermoelectric converters 14, as discussed in more detailed below. More specifically, in this example the radiation-absorbing layer 1a can be formed of a material that exhibits high absorption for solar radiation (e.g., wavelengths less than about 1.5, 2, 3, or 4 microns) while exhibiting low emissivity, and hence low absorption (e.g., for wavelengths greater than about 1.5, 2, 3, or 4 microns).

The absorption of the solar radiation causes generation of heat in the absorbing layer 1a, which can be transmitted via a thermally conductive intermediate layer 2 to a thermally conductive back layer 3a. The thermoelectric converters 14 are thermally coupled at an end 15 to the back layer 3a to receive at least a portion of the generated heat. In this manner, the end 15 of the converters (herein also referred to as the high-temperature end) is maintained at an elevated temperature. With the opposed end 16 of the converters exposed to a lower temperature, the thermoelectric converters can generate electrical energy. As discussed in more detail below, the upper radiation absorbing layer la exhibits a high lateral thermal conductance (i.e., a high thermal conductance in directions tangent to the front surface lb) to more effectively transmit the generated heat to the converters.

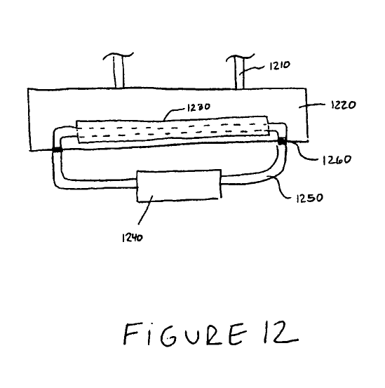

In some embodiments, such as depicted in FIG. 1, a base or a backing structure 10 (also known as a support structure) is coupled to low-temperature ends 16 of the thermoelectric converters to provide structural support and/or to transfer heat away from the ends 16, i.e., acting as a heat spreader. For instance, the backing structure 10 can be thermally coupled to a heat exchanger in which the fluid provided for use or additional power generation is heated. For instance, as depicted in FIG. 12, a backing structure or base 1220 is in thermal communication with a thermoelectric converter 1210.

The fluid conduit 1250 for a solar fluid heating system or a solar thermal power plant is thermally and physically integrated with the thermoelectric device 13. Specifically, the conduit 1250 is coupled to the backing structure 1220 to remove heat therefrom. Vacuum-tight fittings 1260 can be utilized to maintain an evacuated environment around the converter 1210. Conduit 1230 can allow heat transfer from the backing structure 1220 into the conduit 1250 which is schematically drawn as a loop which is provided into a structure 1240 such as a building for hot water generation or to a power plant for steam driven power generation. Other thermal conductive structures coupled to opposed ends 16 of the thermoelectric converters can also be utilized as depicted in FIG. 1.

For the generator (i.e., thermoelectric device) 13 shown in FIG. 1, electrodes 9 are depicted for coupling the generator 13 to an electrical load. Electrically conductive leads 4, 11 are also depicted in FIG. 1, which can provide appropriate electrical coupling within and/or between thermoelectric converters, and can be used to extract electrical energy generated by the converters 14.

The solar-electrical generator 13 depicted in FIG. 1 is adapted to have a flat panel configuration, i.e., the generator 13 has at least one dimensional extent 18, representative of the solar capture surface, greater than at least one other dimensional extent 17 that is not representative of the solar capture surface. Such a configuration can advantageously increase the area available for solar radiation capture while providing sufficient thermal concentration to allow a sufficient temperature difference to be established across the thermoelectric converter to generate substantial electricity. A flat panel configuration can find practical application by providing a low profile device that can be utilized on rooftops or other man-made structures. While the device shown in FIG. 1 is depicted with a flat panel configuration, it is understood that the device of FIG. 1, and others, can be also be configured in non-flat configurations while maintaining operability.

In many embodiments, the radiation-absorbing portion of the capture structure can exhibit, at least in portions thereof, a high lateral thermal conductance, e.g., a lateral thermal conductance large enough that the temperature difference across the absorbing surface is small (e.g., less than about 100° C., 50° C., 10° C., 5° C. or 1° C.), to act as an efficient thermal concentrator for transferring heat to the high-temperature ends of the thermoelectric converters. In some embodiments, such as depicted by the substrate layer 2 in FIG. 1, a radiation-capture structure can also exhibit a high thermal conductance in a transverse (e.g., in this case in a direction substantially orthogonal to the absorbing surface 1b) and/or lateral direction to facilitate transfer of heat from the absorbing layer to the converters. For instance, the capture structure can include a radiation-absorbing layer formed of a material with high thermal conductivity, e.g., above about 20 W/m K or in a range of about 20 W/m K to about 400 W/m K. In some embodiments, a thin film can be deposited on a substrate with such thermal conductivity values. High thermal conductance can also be achieved using thicker materials with lower thermal conductivities. Instances of materials that can be used include any combination of metals (e.g., copper-containing, aluminum-containing), ceramics, anisotropic materials such as oriented polymers (e.g., having a sufficient thermal conductance is a desired direction such as in a plane of a layer), and glasses. While the high thermal conductance properties of a capture structure are exemplified by a unitary substrate layer 2 in FIG. 1, it is understood that multiple structures, such as a plurality of layered materials, can also be used to provide the high thermal conductance property desired in some embodiments.

In some embodiments, a capture structure can include a number of components adapted to provide one or more advantageous functions. For instance, the radiation-absorbing layer 1a of the capture structure 12 shown in FIG. 1 can be adapted to selectively absorb solar radiation. For example, the radiation-absorbing layer 1a can be adapted to absorb solar radiation having wavelengths smaller than about 1.5, 2, or 3 microns, or having wavelengths between about 50 nm and about 1.5, 2, or 3 microns, or having wavelengths between about 200 nm and about 1.5, 2, or 3 microns. In terms of the fraction of impinged solar radiation that can be absorbed, the absorbing layer 1a can be adapted to exhibit an absorptivity of solar radiation that can be greater than about 70%, 75%, 80%, 85%, 90%, 95%, 96%, 97%, 98%, or 99%. For example, the radiation absorbing layer 1a can achieve such absorptivity for solar radiation wavelengths in a range of about 50 nm to about 3 microns. In some embodiments, the absorbing layer 1a can comprise one or more coatings that are applied to a substrate 2 to provide the desired selective solar absorptivity properties. One or more selective coatings can be embodied by one or more layers of hetero-materials with different optical indices, i.e., a one-dimensional photonic structure. A selective coating can also be embodied as a grating, surface texture, or other suitable two-dimensional structure. In another example, a selective coating can be embodied by alloying or compositing two or more types of materials, including nano-composites. The substrate 2 can also be part of the selective surface 1b.

In some embodiments, a capture structure's front surface, or other surface adapted to be exposed to solar radiation, can exhibit low emissivity properties over a wavelength range, e.g., at radiation wavelengths greater than about 1.5, 2, 3, or 4 microns. For example, in the above radiation capture structure 12, the front surface 1b can exhibit an emissivity at wavelengths greater than about 3 microns that is less than about 0.3, or less than 0.1, or less than about 0.05, or more preferably less than about 0.01. Such a low emissivity surface can reduce the heat loss from the solar capture structure due to radiative emission. Although such low emissivity can also reduce absorption of solar radiation wavelengths greater than about 1.5, 2, 3, or 4 microns, its effect on absorption is minimal as solar irradiance drops significantly at such wavelengths. In this exemplary embodiment, not only the front surface 1b but also a back surface 3a of the radiation capture structure 12 exhibits a low emissivity. The back surface does not need to be wavelength selective, and its emissivity should be small, in the range of less than 0.5, or less than 0.3, or less than 0.1, or less than about 0.05. The tolerance for high emissivity values depend on the thermal concentration ratio—the ratio of the total solar absorbing surface area to the total cross-sectional area of the thermoelectric legs. The larger is this ratio, the smaller the emissivity should be. The low-emissivity characteristics of the front surface 1b and the back surface 3a do not need to be identical. In some other embodiments, only one of the front and the back surfaces can exhibit low emissivity.

Furthermore, an inner surface 3b of the backing structure 10, which faces the back surface 3a of the radiation capture structure 12, can exhibit low emissivity. The low emissivity can be over all wavelengths, or can be over wavelengths greater than about 1.5, 2, 3, or 4 microns. The low emissivity characteristics of the inner surface 3b can be similar to that of the back surface 3a of the radiation capture structure, or it can be different. The combination of the low emissivity of the back surface 3a of the capture structure 12 and that of the inner surface 3b of the back structure 10 minimizes radiation heat transfer between these two surfaces, and hence facilitates generation of a temperature differential across the thermoelectric converters.

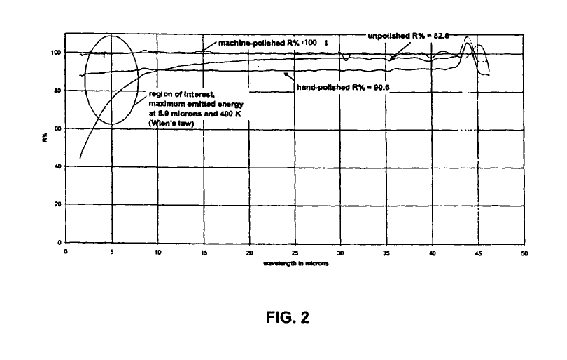

The inner surface 3b can be formed of the same material as the remainder of the backing structure 10, especially when the backing structure is formed of metal (in this case, the electrical isolation among thermoelectric legs should be provided so that electrical current flows in designed sequence, usually in series and sometimes a combination of serial and parallel connections, through all legs). Alternatively, the inner surface 3b can be formed of a different material than the remainder of the backing structure 10, e.g., a different metal having enhanced reflectivity in the infrared. This layer or coating can be a continuous layer, or divided into different regions electrically insulated from each other, or divided into regions electrically coupled together, which can act as interconnects for thermoelectric elements as well. Coatings with high reflectivity, such as gold, can act as low radiative emitters. In general, polished metals can exhibit higher reflectivities, and hence lower emissivities, relative to rough metal surfaces. As shown in FIG. 2, copper surfaces that are polished to better refinements result in surfaces with higher reflectivities, i.e., machine polished copper surfaces have the highest reflectivities, followed by hand polished copper surfaces, and unpolished copper surfaces. The reflectivity measurements of FIG. 2 may have a 3-5% error because the reference aluminum mirror may have reflectivity slightly lower than unity. Such high reflectivities over a wavelength range correspond to low emissivities over that wavelength range, as the sum of reflectivity and a respective emissivity is unity. As well, unoxidized surfaces tend to have lower emissivities relative to oxidized surfaces.

Using any combination of the low emissivity surfaces 1b, 3a, 3b can act to hinder heat transfer away from the capture structure 12, and thus maintain a substantial temperature gradient across the thermoelectric converters 14. When multiple low emissivity surfaces are utilized, the surfaces can have similar properties, or can differ in their emissivity characteristics. In some embodiments, the low emissivity properties of one or more structures can be exhibited over a selected temperature range such as the temperature range that the solar capture surface, or other portions of a capture structure, are subjected to during operation of the solar-electrical generator. For example, the low emissivity properties can be exhibited over a temperature range of about 0° C. to about 1000° C., or about 50° C. to about 500° C., or about 50° C. to about 300° C., or about 100° C. to about 300° C. In some embodiments, the low emissivity properties of any layer(s) can be exhibited over one or more wavelengths of the electromagnetic spectrum. For example, the low emission of any layer(s) can be over wavelengths longer than about 1.5, 2, 3, or 4 microns. In other embodiments, the low emissivity of any layer(s) can be characterized by a surface having a total emissivity value less than about 0.1, less than about 0.05, less than about 0.02, or less than about 0.01 at their working temperature.

In some embodiments, a surface can comprise one or more coatings that are applied thereto in order to provide the desired low emissivity properties, as described earlier. In another instance, low emissivity can be achieved by using multilayered metallodielectric photonic crystals, as described in the publication by Narayanasywamy, A. et al, “Thermal emission control with one-dimensional metallodielectric photonic crystals,” Physical Review B, 70, 125101-1 (2004), which is incorporated herein by reference in its entirety. In some embodiments, other structures can also act as a portion of the low emissivity surface. For instance, with reference to the embodiments exemplified by FIG. 1, the substrate 2 can also be part of the low emissivity surface 1b. For example, a highly reflective metal used as the substrate can be also act as a low emissivity surface in the infrared range, while one or more coatings on top of the metal can be designed to absorb solar radiation.

In some embodiments, an outer surface of the backing structure (e.g., surface 19 in the exemplary solar generator 13) in FIG. 1 can exhibit a high emissivity, e.g., for infrared radiation wavelengths, so as to facilitate radiative cooling. This can be achieved, for example, by depositing an appropriate coating layer on the outer surface of the backing structure.

In the embodiments represented by FIG. 1, among other embodiments herein, a solar-electrical generator can include a portion that is encapsulated (e.g., by a housing) such that the portion is subjected to an isolated environment 6 (e.g., evacuated relative to atmospheric pressure). Preferably, the isolated environment is selected to minimize heat transfer away from the capture structure 12. Accordingly, some embodiments utilize an evacuated environment at a pressure substantially lower than atmospheric pressure. For instance, the evacuated environment can have a pressure less than about 1 mtorr or less than about 10⁻⁶ ton. As depicted in FIG. 1, a housing 5 can encapsulate the entire device 13. At least the top surface of the housing 5 can be substantially transparent to solar radiation, e.g., having high transmissivity and low reflectivity and absorptivity to solar radiation. Potential materials that can be utilized include different types of glasses or translucent plastics. One or more coatings can be applied to one or more sides of the housing walls to impart desired properties (e.g., low reflection losses). In some embodiments, the capture structure 12 can have little to no physical contact with the housing 5 to reduce possible heat transfer away from the capture structure 12. While the embodiments represented by FIG. 1 can utilize a housing 5 that substantially encapsulates the entire solar-electrical generator structure 13, other embodiments can be configured in alternative manners. For example, the solar capture surface 1b can be unencapsulated to receive direct incident solar radiation, while the remainder of the device 13, or the region between the inner surfaces 3a, 3b, can be encapsulated to be in an evacuated environment. It should be noted that the unevacuated environment will generally not be suitable for flat panel type device without any optical concentration, but may be suitable if thermal concentration is combined with optical concentration. The reason is that in flat panel type devices without optical concentration, the absorber surface area is large compared to leg cross-section. If the device is not evacuated, it losses heat to ambient by convection and reduces efficiency. Housings or other structures to contain the evacuated environment can be constructed in any acceptable manner, including within the knowledge of those skilled in the art.

In alternative embodiments, the housing and enclosures discussed herein can be used to enclose an isolated environment, which can be characterized by low heat conductance (e.g., relative to the ambient atmosphere). Accordingly in place of a vacuum, an enclosed environment can include a gas with low thermal conductivity such as an inert gas (e.g., a noble gas such as argon). In another example, insulating materials can be included within an enclosure to limit heat transfer. For instance, the back surface of a capture surface and the inner surface of a backing structure can include a material attached thereto to provide additional insulation beyond the use of low emissivity layer. Thus, embodiments discussed herein which utilize an “evacuated environment” can also be practiced using these alternative environments. Examples of such insulating materials are aerogels and multilayer insulations. However, this is not preferred due to large empty space between absorber and substrate.

Thermoelectric converters, such as the converters 14 depicted in FIG. 1, can generate electricity when a sufficient temperature difference is established across them. In some embodiments, a thermoelectric converter element comprises a p-type thermoelectric leg and a n-type thermoelectric leg, the legs are thermally and electrically coupled at one end, e.g., to form a junction such as a pn junction or p-metal-n junction. The junction can include, or be coupled to, a radiation-capture structure, which can act as a thermal concentrator, consistent with structures discussed herein. A wide variety of materials can be utilized for thermoelectric converters. In general, it can be advantageous to utilize materials having large ZT values (e.g., material with an average ZT value greater than about 0.5, 0.8, 1, 1.2, 1.4, 1.6, 1.8, 2, 3, 4, or 5). Some examples of such materials are described in U.S. Patent Application Publication No. US 2006-0102224 A1, bearing Ser. No. 10/977,363 filed Oct. 29, 2004, and in a U.S. Provisional Patent Application bearing Ser. No. 60/872,242, filed Dec. 1, 2006, entitled “Methods for High-Figure-of-Merit in Nanostructured Thermoelectric Materials;” both of which are hereby incorporated by reference herein in their entirety.

With regard to p-type and n-type materials, such doping of materials can be performed, for example, using techniques known to the skilled artisan. The doped materials can be substantially a single material with certain levels of doping, or can comprise several materials utilized in combination, which are known in some instances as segmented configurations. Thermal electric converters can also utilize cascade thermoelectric generators, where two or more different generators are coupled, each generator operating at in a different temperature range. For instance, each p-n pair can be a stack of p-n pairs, each pair designed to work at a selected temperature. In some instances, segmented configurations and/or cascade configurations are adapted for use over a large temperature range so that appropriate materials are used in the temperature range that they perform best.

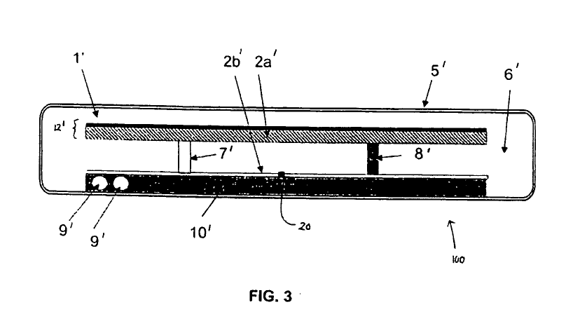

The arrangements of the p-type and n-type elements can vary in any manner that results in an operational solar-electrical generator. For instance, the p-type and n-type elements can be arranged in a pattern that has periodicity or lacks periodicity. FIG. 1 presents one example where p-type and n-type legs 7, 8 are clustered closely together to form a thermoelectric converter 14. Clusters of converter legs, or individual converter legs, can be equally or unequally spaced apart. Pairs of p-type and n-type elements can be used in any number including simply one pair. Another potential configuration can space p-type and n-type elements further apart, as exemplified by the solar-electrical generator 100 shown in FIG. 3. The device 100 is similar in some respects to the solar-electrical generator 13 shown in FIG. 1, having a barrier structure 5′ for providing an evacuated environment 6′ relative to atmospheric pressure, a capture structure 12′ with a capture surface 1′, a backing structure 10′, and electrodes 9′. The capture structure 12′ and the backing structure 10′ can be formed of a metallic material. The metallic material, which can form a layer 2b′, can act as a heat spreader in the backing structure 10′, and in layers 2a′, 2b′ to provide electrical coupling between thermoelectric structures 7′, 8′ on both ends of the structures 7′, 8′. Note that the layer 2b′ on the backing structure 10′ is separated by an insulating segment 20 to prevent short circuiting of the structures 7′, 8′. Accordingly, it is understood that a coating and/or layer as utilized in various embodiments herein can be continuous or discontinuous to provide desired functionality, such as a desired configuration of electrical coupling. Optionally, one or both of the metallic material 2a′, 2b′ surfaces can be polished to have low emissivity, consistent with some embodiments described herein. In the device 100 depicted in FIG. 3, the n-type thermoelectric element 7′ and p-type thermoelectric element 8′ are spaced further apart relative to what is shown in FIG. 1. When a plurality of thermoelectric converter elements are utilized in a solar-thermoelectric generator, p-type and n-type thermoelectric elements can be spaced apart (e.g., evenly) as opposed to being clustered together. For instance, considering heat losses to be due only to radiation, and using a copper material as an absorber, the spacing between legs can be as large as 0.3 m. For example, for use of the generator 13 with a solar water heating system, the legs may be further spaced apart that for use of the generator 13 with a solar thermal power plant. For example, the legs may be spaced apart by 15 to 50 mm, such as about 25 to about 30 mm, for use with a solar water heating system. The legs may be spaced apart by less than 20 mm, such as 1 to 15 mm for use with a solar thermal plant.

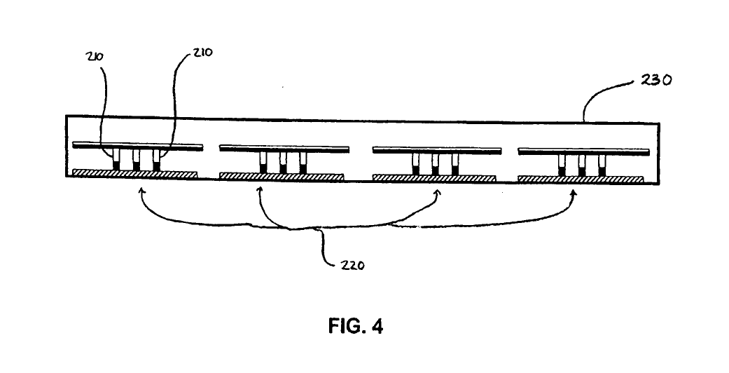

Another potential arrangement of thermoelectric converter elements is depicted in FIG. 4, where multiple thermoelectric converter elements (legs) 210 of a plurality of thermoelectric converters are clustered into groups 220 that are spaced apart. The groups 220 of thermoelectric converter elements 210 are encapsulated by a barrier 230 to enclose the ensemble in an evacuated environment. Such an arrangement can be advantageously utilized when solar radiation is non-uniformly distributed over one or more solar capture surfaces as in embodiments that utilize optical concentrators as described herein. Even if an optical concentrator is not utilized, the arrangement of converter elements could, for example, be configured to follow the path of a sunspot as it travels throughout a day over a capture surface. For the arrangement shown in FIG. 4, the groups are physically separated. It is understood, however, that a device could be embodied as a single entity with groups of converter elements sparsely separated from one another.

The spatial distribution of thermoelectric converter elements can also impact the electrical generation performance of a solar-thermoelectric generator. In some embodiments, the thermoelectric converter elements are spatially arranged such that a minimum temperature difference can be established between a high-temperature portion and a low-temperature portion of a thermoelectric converter element. The minimum temperature difference can be greater than about 40° C., 50° C., 60° C., 70° C., 80° C., 100° C., 150° C., 200° C., 250° C., 280° C., or 300° C. In some cases, such temperature differentials across the thermoelectric converters can be achieved by maintaining the low-temperature ends of the converters at a temperature below about 95° C., 90° C., 80° C., 70° C., 60° C., or preferably below about 50° C., while raising the high-temperature ends of the converters to a temperature no greater than about 350° C., when optical concentration is not employed. For low solar concentration (e.g., a concentration no greater than about 2 to about 4 times incident solar radiation), the temperature can be no greater than about 500° C. Such temperature differentials can assure that the solar-thermoelectric generator operates at a high efficiency. In particular, these temperature specifications can be utilized for a thermoelectric generator that utilizes only incident solar radiation (i.e., unconcentrated radiation) and/or concentrated solar radiation.

Alternatively, or in addition, embodiments can utilize a spatial distribution of thermoelectric converter(s) that provide a limited thermal conductance between their respective ends. While most of heat is designed to go through the thermoelectric converters, meaning that the converter thermal conductance will be more than 50%, even larger than 95% of the total thermal conductance. Otherwise, most heat will be leaking from other conducting paths. However, the converters should be designed with a small thermal conductivity for the legs. Thermal conductance can also be limited by the length of a leg of a thermoelectric converter—longer legs allowing for less, thermal conductance. Accordingly, some embodiments limit the ratio of the cross-sectional area to the length of a leg to help decrease thermal conductance by the leg. For example, the ratio of the cross-sectional area of a leg to the leg's length can be in a range from about 0.0001 meters to about 1 meter. Total cross-sectional area reduction from the solar absorber to the set of thermoelectric converters that are on the order of 10:1 and 1000:1 may also be use used.

In some embodiments, the thermoelectric converters and/or legs of the converters can be distributed in a sparse manner (e.g., relative to the solar capture surface or a backing structure). Sparse distribution of thermoelectric elements can help reduce heat removal via the elements from their high-temperature ends to their low-temperature ends. The arrangements depicted in FIGS. 1 and 3 of thermoelectric converter elements provides some illustrative embodiments of sparsely distributed elements.

In some embodiments where one or more thermoelectric converter elements are sparsely distributed relative to a solar capture surface, the sparseness can be measured by the relative ratio of a solar capture area (herein “capture area”) to a total cross-sectional area associated with converter elements (herein “converter area”). The capture area can be defined by the total amount of area of a selected solar capture surface available for being exposed to solar radiation to generate heat. The converter area can be defined by the total effective cross sectional area of the thermoelectric converter element(s). For instance, with respect to FIG. 1, assuming that all 4 p-type and n-type elements are geometrically similar with uniform cross-sectional areas, the “converter area” can be defined as 4 times the cross-sectional area of a p-type or n-type element, the cross-section of each element being defined by a cross-sectional surface area lying in a putative plane parallel to the capture surface 1b intersecting that element. In general, as the ratio of capture area to converter area increases, the distribution of converter elements becomes more sparse, i.e., there are fewer thermoelectric converter elements relative to the total amount of solar capture surface.

Various embodiments disclosed herein can utilize a range of capture area-to-converter area ratios. In some embodiments, a solar-electrical generator can be characterized by a ratio of capture area to converter area equal or greater than about 200, about 400, about 500, or about 600. Such embodiments can be advantageous, particularly when utilized with solar-thermoelectric generators having a flat panel configuration that captures solar radiation without the use of a solar concentrator. In some embodiments, a solar-thermoelectric generator can be characterized by a ratio of capture area to converter area greater than about 2, 5, 10, 50, 100, 200, or 300. Such embodiments can be advantageous, particularly when utilized with solar-electrical generators which capture concentrated solar radiation (i.e., a solar concentrator is used to collect and concentrate incident solar radiation onto a solar capture surface). Though the embodiments discussed may be advantageous for the particular configurations discussed, it is understood that the scope of such embodiments are not limited to such particular configurations.

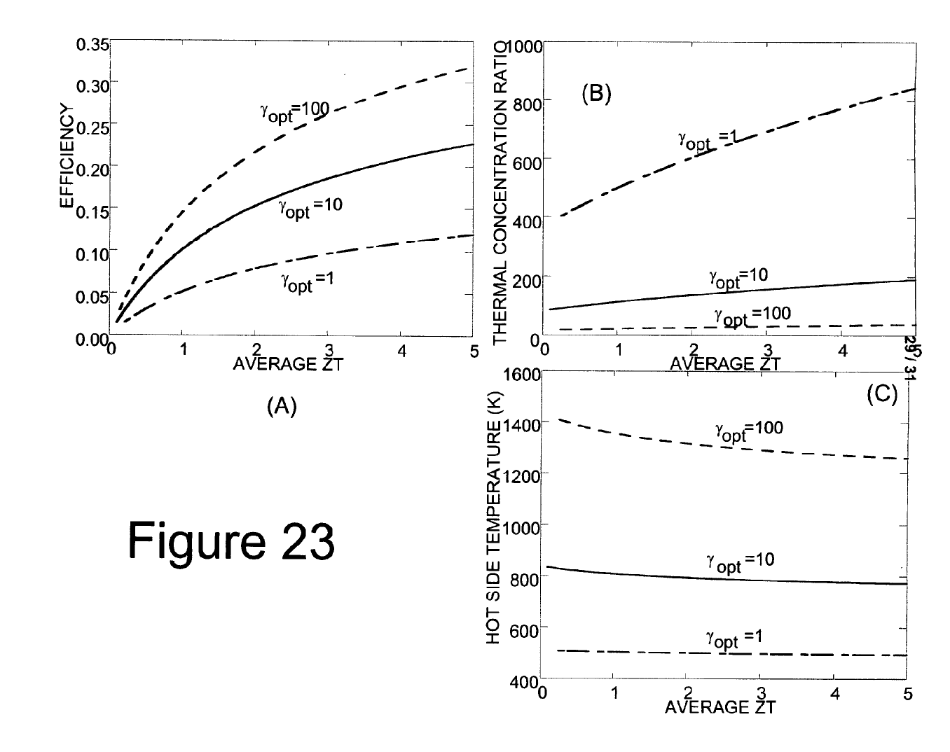

As examples, FIG. 23 shows some exemplary calculations of the efficiency of solar thermoelectric converters. FIG. 23A shows efficiency as a function of nondimensional figure of merit ZT for different optical concentration ratio. Corresponding to each optical concentration ratio, there is also an optimal thermal concentration ratio (the ratio of solar absorbing surface to the total cross-sectional area of the thermoelectric legs). It is understood that these legs may be arranged in different configurations, some are illustrated in FIG. 1 and FIG. 3. Sometimes, a fraction of them can be group together and while other times they can be sparsely and evenly spaced, and yet other times, they can be irregularly spaced. It is understood that in each of these possible configurations, the temperature nonuniformity in the absorber surface is small, preferably be maintained within 1° C., or 5° C., or 10° C., or 50° C., or 100° C. FIG. 23C shows the hot side temperature for the simulated conditions (with the given optical concentration, selective surface properties, etc.). Based on these figures, it is apparent that for each optical concentration ratio, there is usually an optimal thermal concentration ratio (that determines the spacing between legs and cross-sectional area of the legs), and an optimal hot surface temperature. The reason that there is an optimal hot side temperature is as follows: if the hot surface temperature is too high; radiation loss from the surface is too large. If the hot surface temperature is too low, the thermoelectric device efficiency drops. It is understood that these are just exemplary situations, and there are various design flexibilities. For example, optical concentration may be used and yet still maintain the hot side temperature at predetermined temperature, by changing the cross-sectional area of thermoelectric legs.

### Optical Concentrator Configurations

Some embodiments disclosed below utilize solar thermoelectric generator configurations that are adapted for use with one or more optical concentrators. An optical concentrator refers to one or more devices capable of collecting incident solar radiation, and concentrating such solar radiation. The optical concentrator can typically also direct the concentrated solar radiation to a target such as a solar capture surface. In many embodiments in which an optical concentrator is utilized, the concentrator can facilitate generation of a higher temperature differential across the thermoelectric converters, via more efficient heating of their high-temperature ends, which can result in potentially higher electrical output by the converters. An optical concentrator can also be potentially utilized with solar capture structures that have a lower thermal concentration capacity (e.g., smaller solar capture surfaces and/or capture structures that can exhibit larger heat losses) while potentially maintaining the performance of the solar-electrical generator. Though the embodiments described with respect to FIGS. 1, 3, and 4 can be adapted for use where incident solar radiation (i.e., unconcentrated) is utilized, such embodiments can also be utilized in conjunction with an optical concentrator, using any number of the features discussed herein. Similarly, some of the solar-thermoelectric generator designs discussed explicitly with reference to a solar concentrator do not necessarily require such a concentrator.

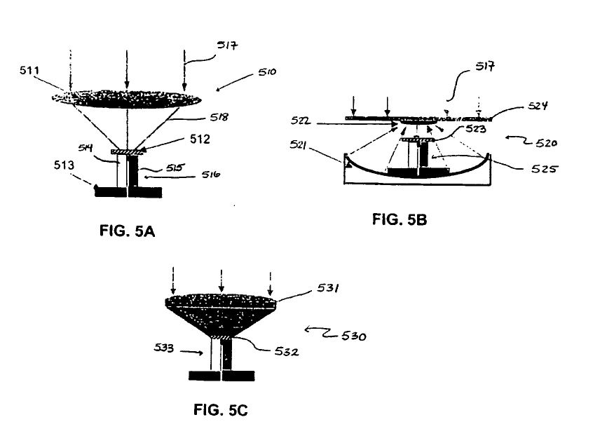

Some embodiments of a solar-thermoelectric generator that includes the use of an optical concentrator are illustrated by the exemplary devices shown in FIGS. 5A-5C. As shown in FIG. 5A, a solar-electrical generator 510 can include an optical concentrator; a radiation-capture structure; a thermoelectric converter element; and a backing structure. For the particular device depicted in FIG. 5A, the optical concentrator is embodied as a transmissive element 511, i.e., an element capable of transmitting solar radiation therethrough. Transmissive elements can be imaging or non-imaging lenses or other transmissive structures capable of concentrating and directing solar radiation. As depicted in FIG. 5A, incident solar radiation 517 can be concentrated by the transmissive element 511 into concentrated solar radiation 518 directed onto a solar capture structure 512 of the radiation-capture structure. In this example, the optical concentrator 511 comprises a convergent optical lens with the radiation capture structure 512 positioned in proximity of its focus to receive the concentrated solar radiation. The concentration of solar radiation can potentially allow the use of a smaller solar capture surface relative to designs that utilize incident solar radiation. Such capture of solar radiation can result in heating of the radiation-capture structure, which can, in turn, heat the thermally coupled ends of the n-type and p-type elements 514, 515 of the thermoelectric converter 516. The backing structure can be configured as a combination electrode/heat spreader 513 structure, which can provide electrical coupling between the n-type and p-type elements 514, 515 and thermal coupling to a heat sink to lower the temperature of the opposed ends of the converter element.

Another embodiment of a solar-electrical generator is depicted in FIG. 5B. For the solar-electrical generator 520, a set of reflective elements 521, 522 act as a solar concentrator. Reflective elements can act to redirect radiation without the radiation passing substantially through the element. Mirrors and structures with other types of reflective coatings can act as a reflective element. For the particular embodiment shown in FIG. 5B, incident solar radiation 517 is directed by structure 524 to mirrored surface 521, which is disposed in this example in proximity of the low-temperature side of the thermoelectric converter 525. The structure 524, which is optionally transparent and/or frame-like, can support the mirror and direct solar radiation downward so that heat spreading can be achieved by a lower substrate. The radiation-reflective element 521 reflects radiation incident thereon to the reflective element 522, which in turn reflects the solar radiation onto radiation capture surface 523 for heating a high-temperature end of the thermoelectric converter 525. In some cases, the reflective element 521 can have a curved shape, e.g., a parabolic, reflective surface that causes the reflective light to be concentrated onto the reflective element 522 (which can be placed, e.g., in proximity of the center of curvature of the reflective element 521). Such concentrated solar radiation is then directed via reflective element 522, which can, in some cases, also provide its own concentration of the solar radiation, onto the radiation capture structure 523.

Another alternative for an optical concentrator is utilized in the embodiment illustrated by FIG. 5C. A solar electrical generator 530 can include a solar collecting transmitter 531 for collecting and concentrating incident solar radiation. The solar collecting transmitter 531 can be closely coupled to a radiation-capture structure 532 (e.g., being in contact or having a very small space or having a thin material in between) to directly channel concentrated solar radiation to the capture structure, potentially resulting in more efficient energy transfer. There can be direct contact between the capture structure 532 and the transmitter 531. Alternatively, a thin thermal insulator (e.g., made of porous glass or a polymeric material) can be lodged between the structures 531, 532. The illustrated embodiment can also be practiced without the need for encapsulating the device in an evacuated environment because of the closer thermal coupling with the thermoelectric converter element 533. As well, when the concentration of solar energy is high (e.g., more than 10 times or 50 times incident solar radiation), convection losses are less important. It is understood, however, that the device could also be utilized in an evacuated environment.

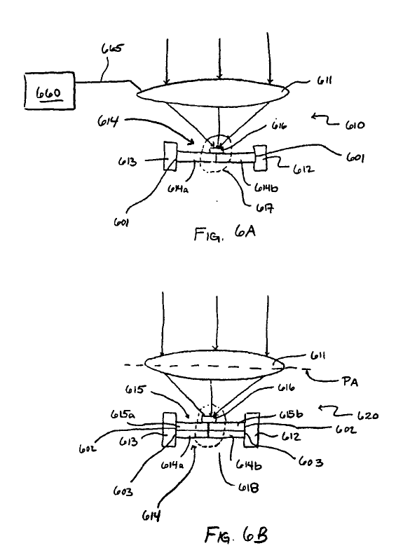

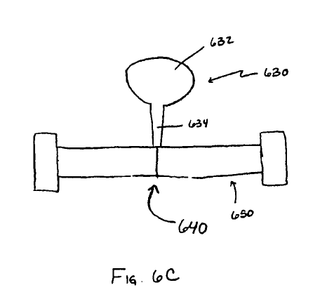

Some embodiments are directed to solar electrical generators in which thermoelectric converters are aligned in alternate configurations relative to those depicted in FIGS. 5A-5C. As shown in FIG. 6A, a thermoelectric converter 614 can be configured so that its n-type and p-type elements (legs) 614a, 614b are aligned along a path such as to have two ends 601. As particularly exemplified in FIG. 6A, ends 601 of the two legs define a substantially linear extent. Here the elements are a p-type leg 614a and a n-type leg 614b, each leg being characterized by an elongated (herein also referred to as axial) direction, though other leg configurations can also be utilized such as curved shapes. In this example, the legs are disposed in a common plane with their axial directions substantially co-aligned. More generally, such legs with axial directions can be disposed in a common plane at an angle relative to one another, where the angle can range from 0 degrees (i.e., co-aligned) to less than about 180 degrees, or about 45 degrees to about 180 degrees, or about 90 degrees to about 180 degrees. In other embodiments, three or more legs can be coupled at varying relative angles. In FIG. 6A, the legs 614a, 614b are aligned in a linear configuration. In particular, the legs 614a, 614b can be horizontally disposed relative to the legs shown in FIGS. 5A-5C, which are vertically-oriented. Such a configuration can provide a number of potential advantages. For instance, the horizontally-oriented legs can provide a more robust mechanical structure vis-à-vis utilizing vertically-oriented legs since the entire device housing for the thermoelectric converter can have a lower profile. The lower profile configuration can aid in the construction of flat-panel configurations for solar-electrical generators and/or providing a smaller volume for encapsulation when such embodiments further utilize an evacuated environment, as discussed herein.

As depicted in FIG. 6A, the elements 614a, 614b share a junction 617 located between the ends 601 of the thermoelectric converter 614. For the embodiment shown here, the junction 617 includes a thermal collector 616 acting as a capture structure, though the junction can also include other types of elements for providing thermal and/or electrical coupling between the elements 614a, 614b. Alternatively, the p-type and n-type elements 614a, 614b can be in physical contact to produce the junction. One or more radiation collectors can be used to collect and capture incident radiation, and direct the concentrated radiation onto the thermoelectric converter so as to heat the junction. For the specific case of FIG. 6A, a lens 611 directs concentrated solar radiation onto the thermal collector 616, which can result in heat generation in the collector 616. As the thermal collector 616 is thermally coupled with the junction 617, it transfers heat generated therein (or at least a portion of such heat) to the junction, thus subjecting the junction 617 to an elevated temperature. A thermal collector 616 can also be a solar radiation absorber, while having low emissivity, as described with respect to other embodiments herein. An example of such a thermal collector material is one or more carbon graphite layers. Further, structures 612, 613 can act as heat spreaders to keep the coupled ends of the elements 614a, 614b at a lower temperature, allowing the thermoelectric converter 614 to generate electricity.

It is understood that a wide variety of geometries can be employed as a capture structure, which can act as a thermal concentrator for directing thermal energy to a junction, as shown in FIGS. 6A and 6B. In some embodiments, it can be advantageous to utilize a capture structure that has a relatively large capture area relative to the junction where thermal energy is directed. FIG. 6C schematically shows one example of a capture structure as a thermally conductive element 630 that can be thermally coupled to the junction 640 of the thermoelectric converter 650 to transfer heat generated therein due to exposure to solar radiation to the junction 640. The thermally conductive element 630 has a mushroom-like shape with a radiation-capture portion 632 that can generate heat in response to exposure to solar radiation. Other shapes can also be utilized. A thermally conductive stem 634 adapted for thermal coupling to the junction 640 provides a thermal path between the radiation-capture portion 632 and the junction 640. Other examples of capture structures with larger capture areas for solar radiation capture relative to the junction areas can also be employed.

While the device 610 shown in FIG. 6A utilizes one thermoelectric converter, it should be understood that other embodiments can utilize a plurality of thermoelectric converters. One example of such a configuration is shown in FIG. 6B, which depicts two thermoelectric converters 614, 615 in a solar-electrical generator 620. Each of the converters 614, 615 can have a p-type leg 614a, 615b and a n-type leg 614b, 615a, where the corresponding p and n-type legs are thermally and electrically coupled. The converters 614, 615 share a common junction 618 that includes a thermal conductor 616. In this embodiment, the p-type and the n-type legs of the two converters are disposed substantially in a common plane. The junction 618 is located between the ends 602, 603 of the converters 615, 614. Optical concentrator 611 directs solar radiation onto the thermal conductor, and hence the junction 618 to heat ends of the converter legs 614a, 614b, 615a, 615b, i.e., the high temperature ends of the converters 614, 615. In this example, the optical concentrator comprises a convergent optical lens which is positioned relative to the thermoelectric converters 615, 614 such that its principal axis PA is substantially parallel to the common plane in which the p-type and n-type thermoelectric legs are disposed. The stacked and horizontal orientation of the converters 614, 615 can act to aid in the design of low-profile, more mechanically-robust solar-electrical generators.

For the various elements depicted in FIGS. 5A, 5B, 5C, 6A, 6B, and 6C such elements can include any of the features or variations associated with such elements as described with respect to various other embodiments of the present invention. Accordingly, the use of one or more low emissivity surfaces, configuring the devices in a flat panel configuration, encapsulating devices or portions thereof in an isolated (e.g., evacuated) environment, and spatially distributing thermoelectric converters can be implemented in any combination, for example.

As well, the embodiments shown in FIGS. 5A, 5B, 5C, 6A, 6B, and 6C can utilize additional components to enhance solar electrical generator performance. For instance, as shown in FIG. 6A, in some embodiments, a solar tracking apparatus 660 can be included to maintain incident solar radiation upon one or more solar concentrator elements 611. Typically, the solar tracking apparatus can include a mechanism 665 for moving one or more elements of a solar concentrator 611 to track the sun's motion to help enhance solar capture. Alternatively, a solar tracking apparatus can also be used in systems without a solar concentrator. In such instances, a thermoelectric module can include a solar capture surface in which the tracking apparatus can move the capture surface to maintain incident solar radiation impingement on the surface. While some of the embodiments discussed herein can be configured to be used without a tracking device, it is understood that solar tracking devices can generally be used in conjunction with any of the embodiments disclosed herein unless explicitly forbidden.

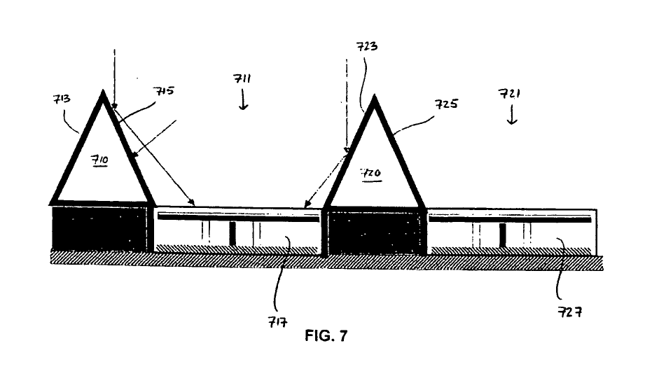

Other embodiments of the invention are directed to solar-electrical generators that utilize a plurality of solar collectors which can concentrate solar radiation in a plurality of regions to provide heating to one or more solar capture structures. Some embodiments utilize a plurality of reflective solar collectors such as exemplified in FIG. 7. As depicted, a plurality of solar collectors 710, 720 are embodied as a set or mirrored surfaces 713, 715, 723, 725 configured to form a plurality of troughs 711, 721. Separate thermoelectric modules 717, 727 can be located in the troughs 711, 721. The mirrored surfaces 713, 715, 723, 725 can reflect solar radiation into the troughs 711, 721 such that the solar radiation impinges upon a capture surface of each of the thermoelectric module 717, 727. This arrangement of the thermoelectric converters and optical concentrators can be extended beyond that shown in the figure. In this case, two slanted reflective surfaces 715, 723 of the solar collectors 710 and 720, which face one another, funnel optical energy onto a radiation-capture surface of the thermoelectric converter 717. Similarly, many of the other thermoelectric converters can receive concentrated solar radiation via reflection of the radiation from two opposed reflective surfaces of two optical concentrators. Such a configuration can be used to provide low level solar radiation concentration (e.g., a solar flux of greater than one and up to about 4 times incident solar radiation). The solar collectors can be adapted such that as the sun and earth move relative to one another, a substantial amount of solar radiation can continually be collected in the troughs. Accordingly, the use of a solar tracker can be avoided in some applications of these embodiments, though in other applications such a tracker may be utilized. In an alternative embodiment, the V-shaped collector of FIG. 7 can be utilized as a secondary collector, where a large solar concentrator with a solar tracking device is used to project solar radiation onto the V-shaped collector. As well, a V-shaped collector can be reduced to be fitted into an isolated environment surrounded by a barrier structure.

The plurality of thermoelectric modules shown in FIG. 7 are embodied as flat panel devices each encapsulated in an evacuated environment. It is understood that other modular configurations, including any of the devices or features of devices disclosed herein, can be utilized instead. In some embodiments, however, the module can be chosen to be consistent with the solar flux that can be generated by such solar collectors (e.g., modules that operate using solar radiation fluxes from 1 to about 4 times incident solar radiation values, which can depend upon collection angles). It is also understood that while FIG. 7 depicts a two-dimensional arrangement, troughs can also be embodied in a three-dimensional arrangement, where each trough is more pit-like, allowing for a three-dimensional distribution of solar-electrical modules.

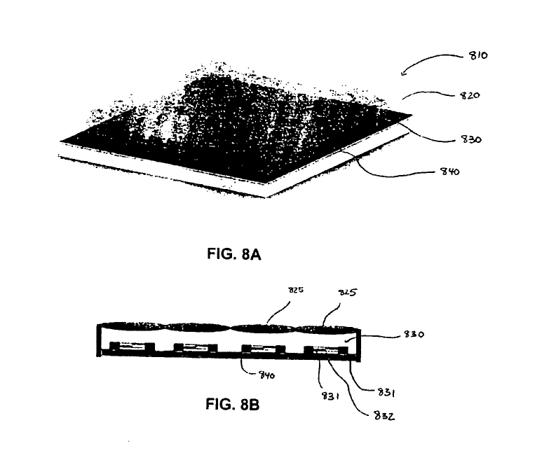

Other embodiments of a solar-electrical generator utilizing a plurality of solar collectors can be configured using different types of solar collectors in different arrangements. For instance, a solar-electrical generator 810 is depicted in a perspective view in FIG. 8A and in a partial cross-sectional view in FIG. 8B. An assembly 820 of solar collectors embodied as a plurality of lens structures 825 serves to capture incident solar radiation. Each of the lens structures 825 can concentrate and direct solar radiation onto a thermoelectric module 830, where for each lens structure 825 a respective module 830 is provided. Each module 830 can be embodied in any number of configurations, including any of the configurations described in the present application. As depicted in FIG. 8B, each module 830 can be configured as a set of thermoelectric converters in a horizontal-orientation; as shown in FIGS. 6A and 6B. Accordingly, the lens structures 825 can be adapted to direct solar radiation onto the corresponding junctions of the modules 830. The modules 830 can be coupled to a backing structure 840, which can optionally be configured as a heat sink to keep ends 831 of the converters at a lower temperature relative to the high temperature ends 832. Like the embodiments exemplified by FIG. 7, the use of the multiple lens structures 825 can direct solar radiation to a specific location, and potentially alleviating the need for a solar tracking device.

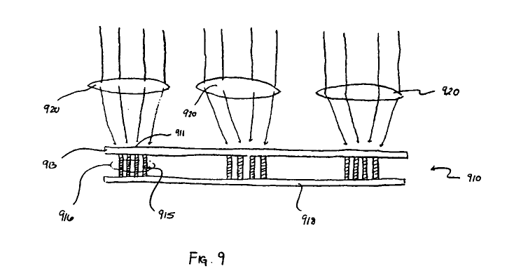

While FIGS. 7 and 8 exemplify some exemplary embodiments in which a plurality of concentrators are used with a plurality of thermoelectric modules, it should be understood that the concentrators can also be configured to be used with a single thermoelectric module. One example of such a configuration is shown in FIG. 9. A set of solar collectors exemplified as lens structures 920 can be used to capture and concentrate incident solar radiation onto a thermoelectric module 910, which can be used to create electricity from the concentrated solar radiation. Such a module can include any number of the features described with respect to the module depicted in FIG. 1 (e.g., low emissivity surfaces, flat panel configuration, and/or evacuated environment). For the particular configuration depicted in FIG. 9, the module 910 can include groupings 916 of p-type legs and n-type legs 915 that are spaced apart relative to a capture structure 913. Each lens structure 920 can be adapted to direct concentrated solar radiation onto a portion 911 of the capture structure solar collection surface, where the portion can correspond with the proximate location of a grouping 916 of legs 915. It is understood that variations in the design of the system depicted in FIG. 9 (as is the case for FIGS. 7 and 8) can be employed consistent with embodiments of the present invention. For example, a different configuration of solar collectors (e.g., using properly configured reflective surfaces) could be employed instead of the lens structures. One optical concentrator can used with respect to the module shown in FIG. 9 as well. In such an instance, the focus/concentrated light spot can move following the sun if the device does not utilize tracking. One thermoelectric unit in the set can produce higher efficiency due to reduced size, and hence a lower radiation loss.

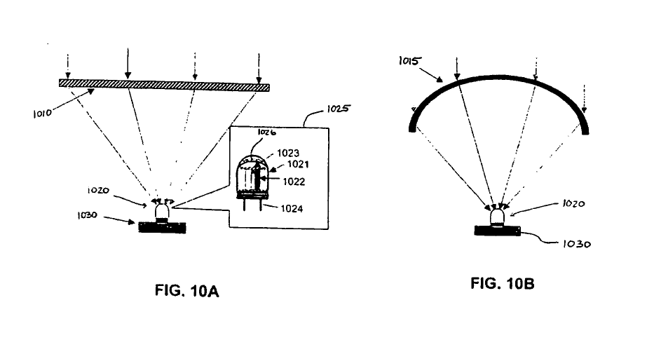

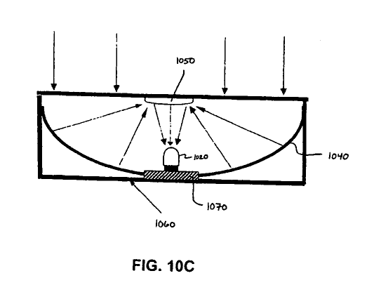

While the embodiments depicted in FIGS. 7-9 have shown the use of a variety of thermoelectric module configurations with solar concentrators, other module designs are also possible. One alternative module design and its use is depicted in FIGS. 10A and 10B. As shown in FIG. 10A, a solar collector 1010, which can be embodied as a Fresnel lens or some other type of diffractive element, is used to focus concentrated solar radiation onto a thermoelectric module 1020, which can be thermally coupled to a heat spreader 1030 (or more generically coupled to a support structure). Other types of potential solar collectors include using one or more lens elements, reflective elements, and/or refractive elements. In some embodiments, the thermoelectric module 1020 can be removably coupled (e.g., mechanically, thermally, and/or electrically) to the heat spreader 1030. Accordingly, the module 1020 can be replaced easily into the heat spreader for enhanced maintenance of such a system.

A more detailed view of the thermoelectric module 1020 is provided in the blow up box 1025 in FIG. 10A. The module 1020 can include a barrier structure 1021 (in this case a bulb-like structure) which encloses the module 1020 in an isolated environment. The isolated environment can be an evacuated environment relative to atmospheric pressure, or can comprise an atmosphere which has low thermal conductance relative to the ambient atmosphere. Examples can include the use of gases having low heat capacities such as an inert gas. Thermally insulating materials can also be incorporated within the barrier structure 1021 to reduce heat loss from high-temperature ends of the thermoelectric module. The barrier can be adapted to be at least partially transmissive to solar radiation, where the barrier can include any number of features as described for the encapsulation with respect to FIG. 1. For the particular configuration shown in FIG. 10A, the barrier structure 1021 forms at least part of a bulb-like enclosure; other geometrical configurations are also contemplated. The barrier structure 1021 can optionally include a lens structure 1026, which can further direct and/or concentrate solar radiation impinging on the barrier structure 1021. Within the enclosure, a radiation-capture structure 1023 can be coupled to the legs 1022 of a thermoelectric converter. Solar radiation impinging on the barrier structure 1021 can be directed onto the capture structure to generate heat, and keep one end of the legs 1022 at a relatively high temperature. Electricity generated by the legs 1022 of the converter can be coupled to an electrical load via electrodes 1024.

Thermoelectric modules that utilize the barrier structure exemplified in FIG. 10A can afford a number of advantages. The module can be configured compactly, having a reduced volume (e.g., relative to the volume of a larger flat panel configuration) to facilitate ease of maintaining an evacuated environment. The use of a solar concentrator (e.g., solar concentrators that provide a high degree of concentration such as greater than about ten times incident solar radiation) can allow the use of smaller capture structures for thermal concentration, which enables the use of smaller volumes. As mentioned previously, such compact structures can also be modular in nature, allowing ease of replacement of such modules. This aspect can be particularly advantageous in configurations that include a multiplicity of modules. For instance, the system depicted in FIGS. 8A and 8B can utilize the encapsulated module 1020 of FIG. 10A instead of the module 830. This can provide for ease of maintenance if one module becomes broken. It is understood, however, that the module 830 of FIGS. 8A and 8B can also be contained in a replaceable modular configuration that is encapsulated.

A variety of other configurations are contemplated beyond what is shown in FIG. 10A, including those modifications apparent to one skilled in the art. For instance, the Fresnel lens concentrator can be configured as a flat structure 1010 as depicted in FIG. 10A, or as a structure having a curve 1015 as shown in FIG. 10B. As well, other types of optical concentrators beyond Fresnel lenses can be used, such as other types of diffractive elements. As shown in FIG. 10C, a solar-electrical device 1060 can utilize two reflectors 1040, 1050 as a solar collector direct solar radiation to the thermoelectric module 1020, akin to what is shown as described with respect to FIG. 5B. The heat spreader 1070 can be thermally coupled to the environment to provide a heat sink. As well, encapsulated designs can utilize a solar tracker, as discussed herein, to maintain solar radiation on a portion of the encapsulated structure. Such designs can aid in maintaining a particular level of concentrated solar radiation on the encapsulated structure (e.g., at least 10 time incident solar radiation). All these variations, and others, are within the scope of the present disclosure.

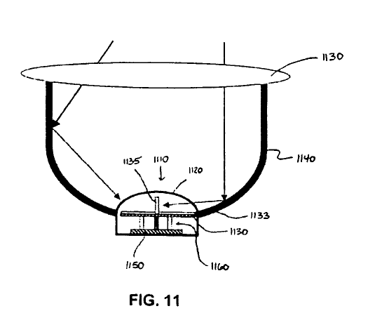

Another modular configuration for use with the various solar-electrical embodiments discussed herein is depicted in FIG. 11. A solar concentrator for use in directing and concentrating solar radiation can include a reflective element 1140 (e.g., a parabolic mirror). Another optical element 1130 (e.g., a convergent lens) can also be used to direct incident solar radiation toward the reflective element 1140. The reflective element 1140 can, in turn, concentrate and direct the solar radiation incident onto the thermoelectric module 1110. The module 1110, which can optionally be encapsulated in an enclosure 1120 to provide an evacuated environment relative to atmospheric pressure, can include a radiation-capture structure 1130, which can include one or more surfaces for absorbing solar radiation. The capture structure can generate heat upon exposure to solar radiation. The capture structure can include one or more protruding elements 1135 that can be adapted to receive some of the solar radiation reflected by the reflective element 1140, and can further be configured to generate heat by absorbing at least a portion of the solar radiation spectrum. For example, as depicted in FIG. 11, the protruding element 1135 is substantially perpendicular to the flat surface 1133 of the capture structure 1130. Accordingly, the parabolic mirror need not be configured to direct light only to a flat surface, but can also direct light on the protruding surfaces. Such a design can be advantageous since it can provide flexibility on the requirements on solar collector designs, and can increase the heat generating capacity of a capture structure. A protruding element can allow a capture structure to absorb solar radiation from a multiplicity of angle and directions (e.g., including directions that cannot be captured by a single flat surface). One or more thermoelectric converters 1160 can be coupled to the capture structure 1130, with one end of the converter thermally coupled to the capture structure and another end coupled to a heat spreader 1150. The protruding element can be composed and designed in accord with any of the capture structures disclosed in the present application (e.g., a metal or other material with high selective solar absorbance and/or low emissivity to infrared light). As well, the design of a module with a protruding element can be in a removably couplable module as discussed with respect to FIGS. 10A-10C.

The following example is provided to illustrate some embodiments of the invention. The example is not intended to limit the scope of any particular embodiment(s) utilized, and is not intended to necessarily indicate an optimal performance of a thermoelectric generator according to the teachings of the invention.

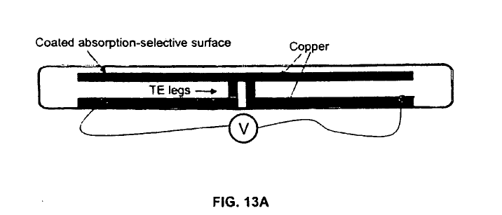

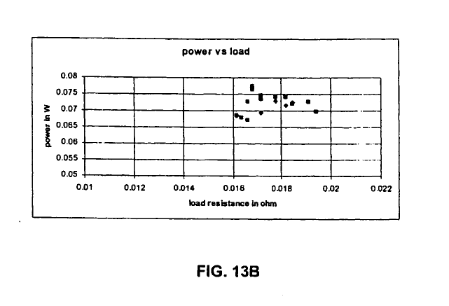

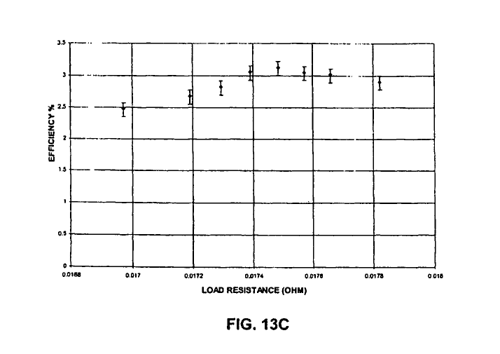

FIG. 13A illustrates a prototype of a thermoelectric generator and its performance. FIG. 13A is a schematic of the prototype. The generator made of one pair of p-type and n-type commercially available thermoelectric elements. A thickness of ˜1 mm is utilized in our thermoelectric elements. The thickness of the legs can be from 20 microns and up to 5 mm. A selective absorber made of copper is attached to the top of the legs and also serves as an electrical interconnect. The experimental apparatus was tested inside a vacuum chamber. The power output from the pair of legs under ˜1000 W/m² illumination is shown in FIG. 13B, and the efficiency is shown in FIG. 13C. This prototype did not use parallel plates and did not attempt to increase the reflectivity of the backside of the absorber. By taking these measures, among others which are disclosed in the present application, higher efficiencies can potentially be achieved.

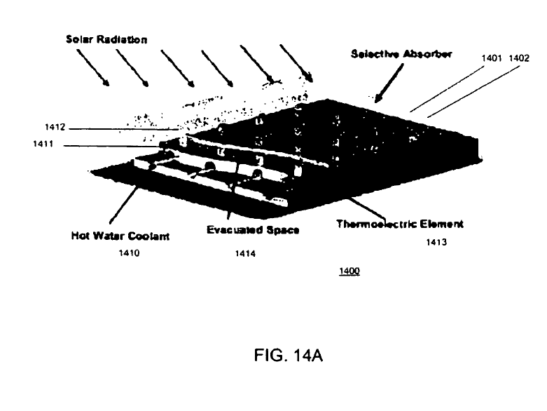

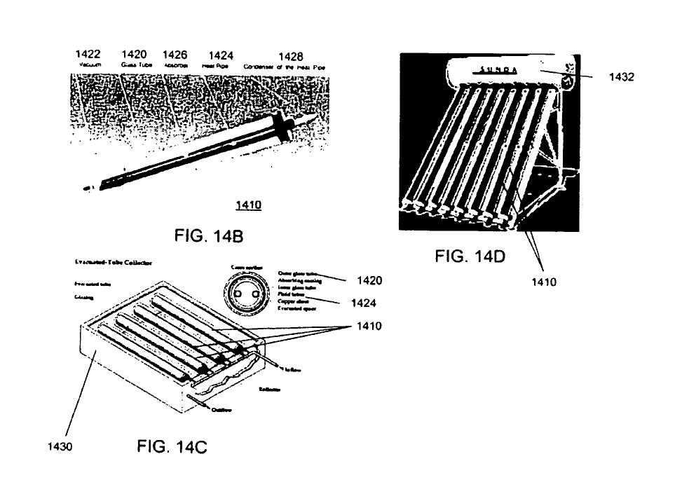

FIG. 14A illustrates an embodiment of a solar thermal-thermoelectric (STTE) converter 1400 used in the cogeneration of solar thermoelectric energy and hot water heat in accordance with the present invention. Solar radiation is incident onto a selective surface 1401 of a solar absorber 1402, such as, for example, the radiation capture structure 12 shown in FIG. 1, of the STTE converter. The selective surface absorbs the solar radiation but emits little thermal radiation, allowing the solar absorber to heat up to designed temperature, for example, in the range of 150-300° C., or 300-500° C. Thermoelectric converters 1413 separate the solar absorber 1402 at a hot-side 1412 of the SITE converter from the set of conduits 1410, such as pipes or plates carrying water, or another fluid, at a cold-side 1411 of the STTE converter. The converters 1413 are located inside the evacuated space 1414.

FIGS. 14B, 14C and 14D illustrate exemplary fluid conduits that may be used in the STTE converter system 1400. Specifically, these figures illustrate conduits used in prior art solar thermal systems that lack the thermoelectric converters, but which can be used together with the thermoelectric devices, such that the conduits are not just fluid carrying tubes, but contain thermoelectric devices that should be on top of them. Specifically, the absorber material in the prior art conduits should be replaced by a thermoelectric device, such as the device shown in FIG. 1, where the bottom substrate of the thermoelectric device is thermally linked to the heat carrying fluid conduits. It should also be noted that the conduits and the external glass tubes do not have to be circular and may have other shapes. For example, FIG. 14B illustrates an evacuated conduit 1410 which contains a glass tube housing 1420 enclosing a vacuum chamber 1422, a fluid carrying heat pipe 1424 coated with an optional thermal absorber 1426 (which may be omitted in system 1400) located in chamber 1422 and an optional condenser 1428 at the end of the heat pipe FIG. 14C illustrates an example of an array of conduits 1410 in a housing 1430 containing fluid carrying inner tubes or pipes 1424 inside outer glass tube housings 1420. The tubes 1420, 1420 do not have to be made of glass, since they do not receive solar radiation, but may be made of a thermally conductive material, such as a metal. FIG. 14D illustrates a plurality of conduits 1410 which are positioned at an angle with respect to the ground and which are connected to a fluid tank 1432 located above the conduits.

Heat absorbed by the solar absorber is conducted to the set of thermoelectric converters 1413, concentrating the heat stored in the solar absorber 1402 at the set of thermoelectric converters 1413, where the conversion from thermal to electrical energy takes place. Heat conducted through the thermoelectric converters themselves from the hot-side 1412 of the STTE converter to the cold-side 1411 of the STTE converter approaches heat transfer levels associated With conventional solar thermal conversion for hot water heating systems. The benefit in the inventive STTE converter over standard solar thermal converters is an additional solar thermoelectric energy conversion, which generates electrical power at less than $1-$2/Watt at current energy prices.

By comparison, current PV cell prices generate electrical power at approximately $4/Watt to $7/Watt current prices, depending on installation costs. In the preferred embodiment of the present invention, the STTE converter installation costs are combined with the installation cost of the hot water systems, reducing the installation cost.

The combination of thermal energy concentration and solar energy concentration can be used to adjust a solar thermoelectric converter to function at an peak operating temperature that leads to maximum efficiency. The peak operating temperature depends on the optical concentration used and the materials available. FIGS. 23A-C illustrate examples of how the peak operational temperature may change with optical concentration ratio, while FIG. 15 presents a series of plots of ZT as a function of temperature for several well-known and currently investigated thermoelectric converter materials. All these materials, and other materials currently available and under development, can be used for solar cogeneration systems. Examples of these materials are: SiGe (e.g., Si₈₀Ge₂₀), Bi₂Te₃: Bi₂Te₃₋ₓSeₓ (n-type)/BiₓSe₂₋ₓTe₃ (p-type), and PbTe, skutterudites (CoSb₃), Zn₃Sb₄, and AgPbₘSbTe₂₊ₘ, and Bi₂Te₃/Sb₂Te₃ quantum dot superlattices (QDSLs), PbTe/PbSeTe QDSLs, and PbAgTe. In general, combination of different materials, in the form of segmented legs (a thermoelectric leg with different materials distributed along the leg) or cascade devices (a stack of devices each operating in certain temperature range) can be used in the solar thermal co-generation systems.

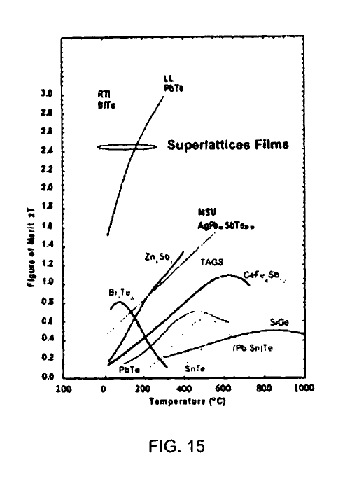

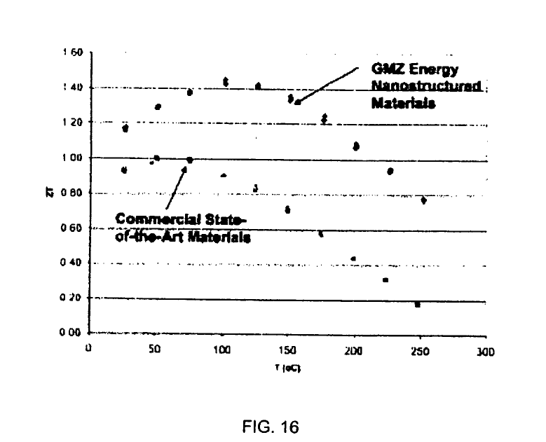

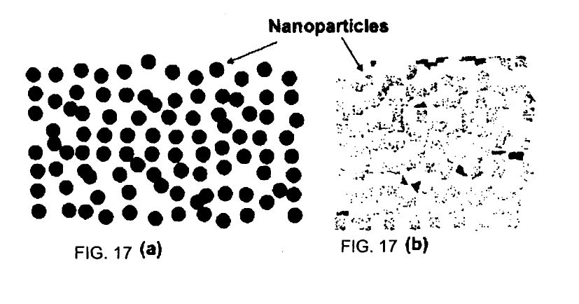

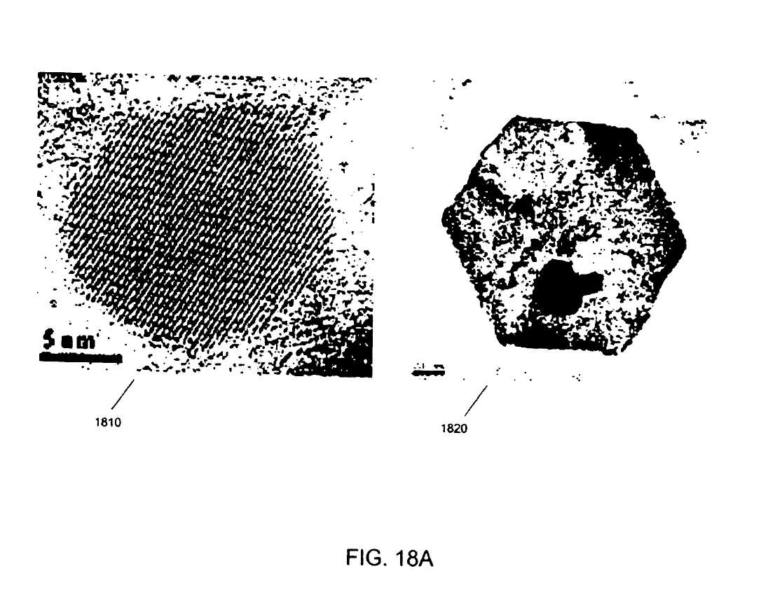

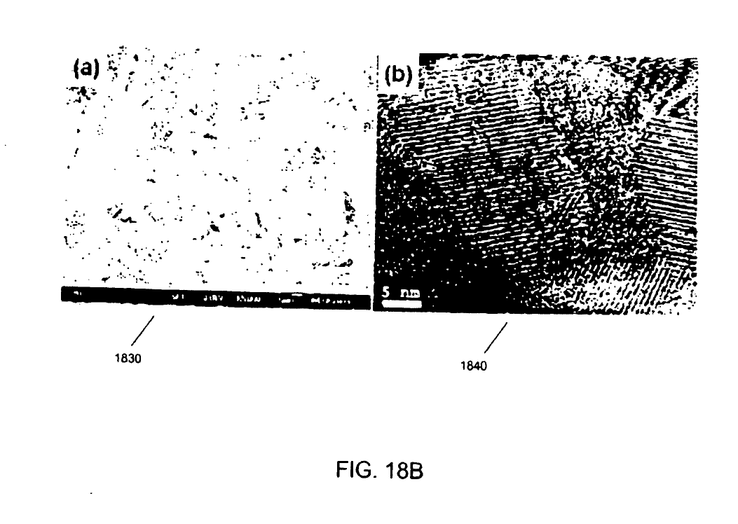

In recent years, significant progresses have been made in improving ZT of thermoelectric materials. Most commercial thermoelectric devices are built on Bi₂Te₃ and its alloys with a peak ZT about 1. Some progress in ZT is summarized in FIG. 15. Among such progress is the discovery of new materials, such as skutterudites, and nanostructuring of existing materials, such as superlattices. The nanostructured bulk materials which comprise compacted semiconductor nanoparticles are particularly attractive since the materials are in a form that is compatible with solar thermal co-generation schemes and yet are with a higher ZT and economical. FIG. 16 shows compares the ZT of nanostructured bulk Bi2Te3 alloy with that of commercial Bi2Te3 alloys, demonstrating improved ZT. Such nanostructured bulk materials can be compacted from nanoparticles of the same material (such as silicon, SiGe, Bi₂Te₃, Sb₂Te₃, etc.) shown in FIG. 17A, or compacted nanoparticles of different materials, in which the nanoparticles of one material form a host matrix and the nanoparticles of the second material form inclusions in the host matrix, as shown in FIG. 17B. The compaction may be conducted using hot pressing or direct current induced hot pressing. FIG. 18A presents TEM images of Bi₂Te₃ 1810 and Bi₂Se₃ 1820 nanoparticles synthesized by wet chemistry and FIG. 18B presents high-resolution SEM 1830 and TEM 1840 images of Bi₂Te₃ based alloy compacted nanopowders. The TEM image, 1840, provides evidence of a nanodomain structure for Bi₂Te₃ based alloy nanopowders.

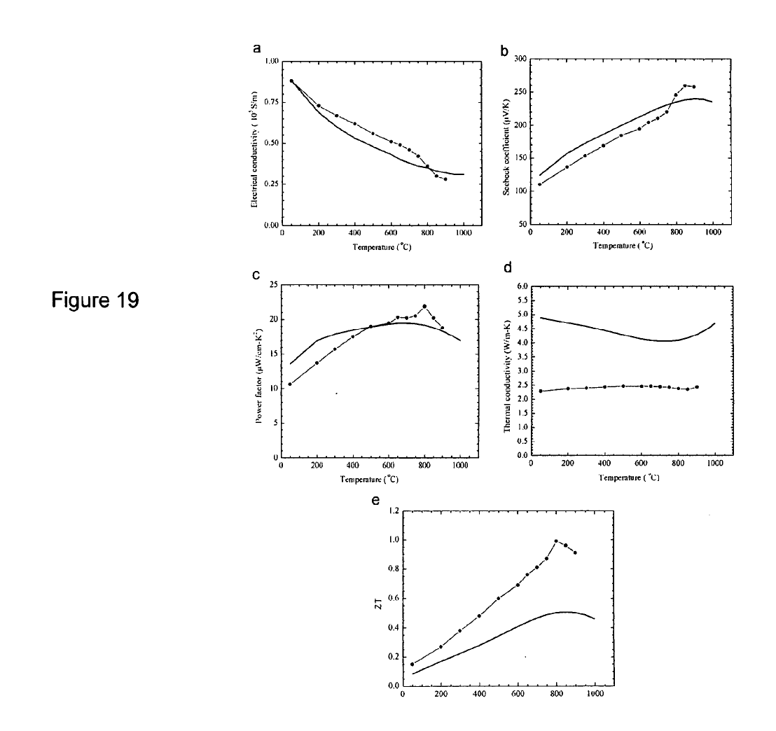

FIGS. 19(a)-(e) show properties of nanostructured bulk SiGe as another example. Nanostructured SiGe alloy particles are prepared by mechanical alloying using a ball mill technique. In this approach, boron (B) powder (99.99%, Aldrich) is added to silicon (Si) (99.99%, Alfa Aesar) and germanium (Ge) (99.99%, Alfa Aesar) chunks in the milling jar. They are then milled for a certain time to get the desired alloyed nanopowders having a mean size of about 20 to 200 nm. The mechanically prepared nanopowders are then pressed at different temperatures by using a dc hot press method to compact the nanopowders in graphite dies. The compacted nanostructured Si₈₀Ge₂₀ materials consist of polycrystalline grains of sizes ranging from 5 to 50 nm with random orientations, such as 5 to 20 nm In FIGS. 19A-E, dots represent nanostructured SiGe, and solid lines represent p-type SiGe used in past NASA flights as radio-isotope power generators (RTG). FIGS. 19A-C show that the electrical transport properties of nanostructured SiGe can be maintained, with a power factor comparable to that of RTG samples. However, the thermal conductivity of the nanostructured bulk samples is much lower than that of the RTG sample (FIG. 19D) over the whole temperature range up to 900° C., which led to a peak ZT of about 1 in nanostructured bulk samples Si₈₀Ge₂₀ (FIG. 19D). Such a peak ZT value is about a 100% improvement over that of the p-type RTG SiGe alloy currently used in space missions, and 60% over that of the reported record. The significant reduction of the thermal conductivity in the nanostructured samples is mainly due to the increased phonon scattering at the numerous interfaces of the random nanostructures.

Solar radiation is incident onto the selective surface of the solar absorber of the STTE converter. The selective surface absorbs the solar radiation but emits little thermal radiation, allowing the solar absorber to store heat. Thermoelectric converter elements separate the solar absorber at a hot-side of the STTE converter elements from the set of conduits, such as pipes carrying water, or another fluid, such as oil or melton salt, at a cold side of the STTE converter elements.

The efficiency of STTE converter depends on the properties of the selective surfaces 1401 of the solar absorber 1402. Solar radiation peaks at a wavelength of about 0.5 μm. Wavelengths longer than 4 μm account for less than 1% of total solar radiation. Less than 0.2% of the radiation emitted from a surface at 300 K has wavelengths shorter than 4 μm. An ideal selective surface of the solar absorber is designed to absorb 100% of the solar radiation and emit 0% of the stored thermal radiation. That is, an ideal selective surface of the solar absorber has an emissivity of 1.0 for wavelengths less than 4 μm and an emissivity of 0.0 for wavelengths greater than 4 μm.

Some commercial selective absorbers have characteristics close to the aforementioned requirements. For example, ALANOD Sunselect GmbH & Co. KG provides materials with absorptivity of 0.95 for solar incident radiation and 0.05 for thermal emission from the selective surface, with a transition wavelength around 2 μm. Low emissivity between a set of inner surfaces separated by the thermoelectric converters 1413 is important to reduce thermal radiation from leaking from the hot-side 1412 of the set of thermoelectric converters 1413 to the cold-side 1411 of the thermoelectric converters.

The solar absorber should be connected to a set of electrical contacts for the set of thermoelectric converters 1413. Solar absorbers patterned on copper foil substrates provide both high lateral thermal conductivity and low resistance electrical contacts to the set of thermoelectric converters. An additional thin layer of gold, or another thin metallic layer, coating the selective surface of the solar absorber and the surface facing the cold-side of the set of thermoelectric converters 1413 can reduce the selective surface emissivity to 0.02 for thermal radiation energies. Additionally, a volume 1414, shown in FIG. 14A, between the hot-side 1412 and the cold-side 1411 is evacuated to limit heat loss from the hot-side to the cold-side by means of convection.

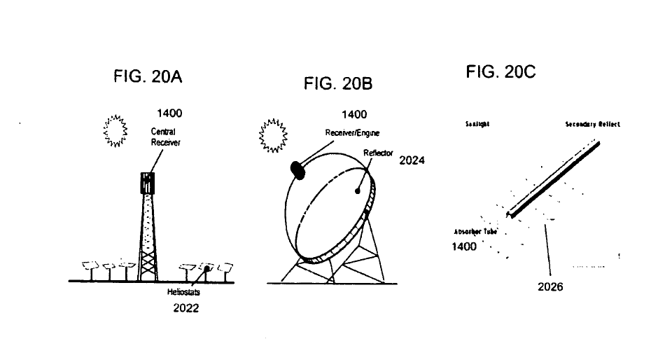

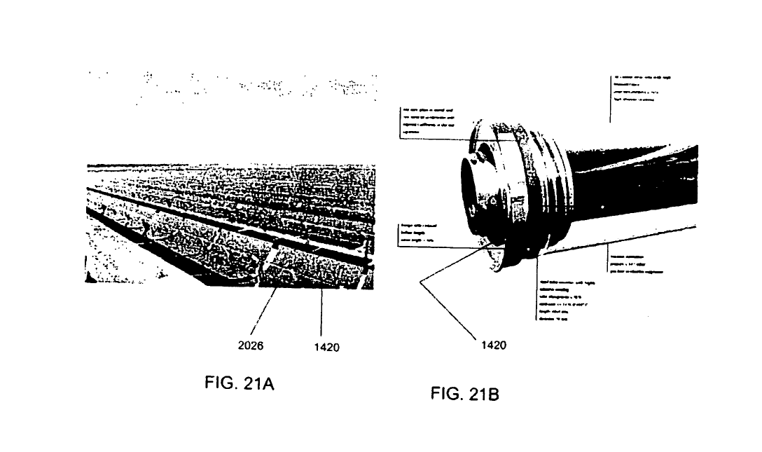

FIGS. 20A-20C illustrate various two dimensional (2D) 2010 and three dimensional (3D) 2020 solar energy flux concentrators for the cogeneration of solar thermoelectric energy and fluids used in current or future thermal power plant in accordance with a preferred embodiment of the present invention. In one embodiment, the thermoelectric device is physically and thermally integrated with a solar thermal plant which heats a fluid and uses the heated fluid to generate electricity. The thermoelectric converters are used as a topping cycle in combination with 2D and 3D solar thermal plants, driving Rankine or Stirling heat engines. 2D and 3D solar concentrators such as heliostats 2022 shown in FIG. 20A, dishes 2024 shown in FIG. 20B, and troughs 2026 shown in FIG. 20C may be used. Solar radiation is focused onto a selective or a non-selective surface, depending on the solar concentrator level. The solar absorbing surface is thermally coupled to a thermoelectric device, and heat rejected at the cold side is used to heat up the fluids used in a thermal power plant to drive mechanical power generation engines (Rankine and Stirling).

The solar absorber 1402 shown in FIG. 14A is coupled thermally to the hot-side 1412 of the thermoelectric converters 1413. The cold-side 1411 of the thermoelectric converters 1413 exchanges heat with a fluid in conduits 1410 that drives Rankine or Stirling heat engines, or any pump based on a thermal-mechanical heat cycle. In a preferred embodiment, heat engines are driven by the fluid directly. In a Stirling converter, the fluid may comprise a gas (if any liquid is present, then it is used only for coupling heat to the Stirling engine which contains a gas inside of it). In the Stirling converter, the solar radiation is focused onto an absorber, and heat generated is transferred to heat up gas inside a Stirling engine. The above described thermoelectric device can be used as a topping cycle for such Stirling engine. Heat rejected in the cold side of thermoelectric device can be provided directly into the gas rather than being provided to the gas via a different fluid. In another preferred embodiment, a heat exchanger (not shown) exchanges heat with a medium external to the thermoelectric converter system and the medium, such as a liquid or gas is used to drive the heat engines. It should be understood that thermoelectric generator illustrated in FIG. 14A is not limiting. All other thermoelectric generator configurations as discussed herein may be used.

FIG. 21A illustrates presents a series of trough concentrators 2026 which may be used in power plants populated by STTE converters used in the cogeneration of solar thermoelectric energy and solar thermal energy in accordance with a preferred embodiment of the present invention. An evacuated tube 1420 passes through a reflective trough 2026 which reflects sunlight onto the tube. The details of an exemplary evacuated tube in accordance with the present invention is given in: http://www.schott.com/hungary/hungarian/download/ptr_{—}70_brochure.pdf

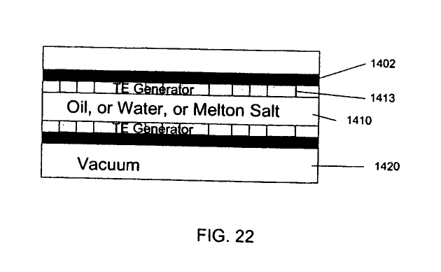

and incorporated herein by reference. The thermoelectric generators as discussed previously will be thermally coupled to these tubes, and preferably situated inside the evacuated tube, with the absorbers thermally linked to the hot side of the thermoelectric generator as shown in FIG. 22.

The fluid exiting the trough through the tube has a temperature of about 40° C. The hot fluid generates electricity in a generator using a Rankine heat engine or steam cycle, as an example. Any suitable heat transfer fluid may be used, such as, but not limited to, water, oil, and melton salt. The hot-side 1412 and the cold-side 1411 of the thermoelectric converters 1413 can be operated at a constant temperature or a variable temperature.

FIG. 22 presents a side view of an individual STTE converter 1400 similar to that shown in FIG. 14A used in the cogeneration of solar thermoelectric energy and solar thermal energy that is used to drive pump using a Rankine cycle in accordance with a preferred embodiment of the present invention. FIG. 22 shows the thermoelectric converters 1413 distributed along the pipes 1410 carrying the same fluid used in the electric plant for power generation. The thermoelectric converters 1413 are formed above the pipes 1410 with respect to the location of the sun. The thermoelectric converters 1413 may fully or partially cover the pipes 1410. The pipes 1410 may have a flat shape, cylindrical shape, or any other reasonable geometric configuration. The pipes and converters may be located in a vacuum inside an outer shell or housing 1420. Different thermoelectric materials can be used along the length of the pipe or other conduit to take advantage of different fluid temperatures along the pipe line. For example, the inlet end of the fluid conduit has a larger temperature difference between the fluid and the thermoelectric converters than the outlet end of the conduit. Thus, thermoelectric converter materials used in thermal contact with the inlet end of the conduit provide for lower temperatures at the cold-side than thermoelectric materials at the outlet end of the conduit. The thermoelectric converters 1413 can operate effectively in pressures from vacuum levels to atmospheric pressure, potentially increasing solar electricity efficiency from 20% to 25-30%.

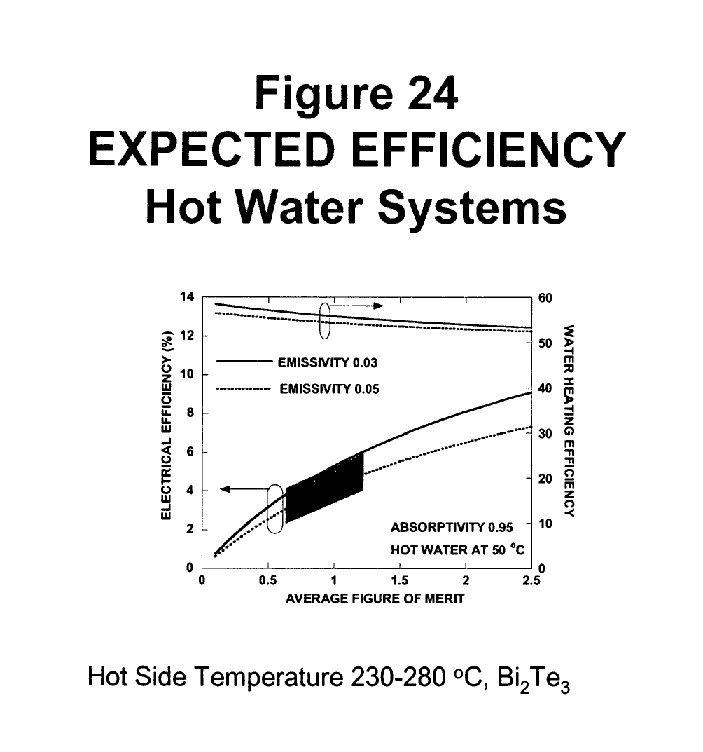

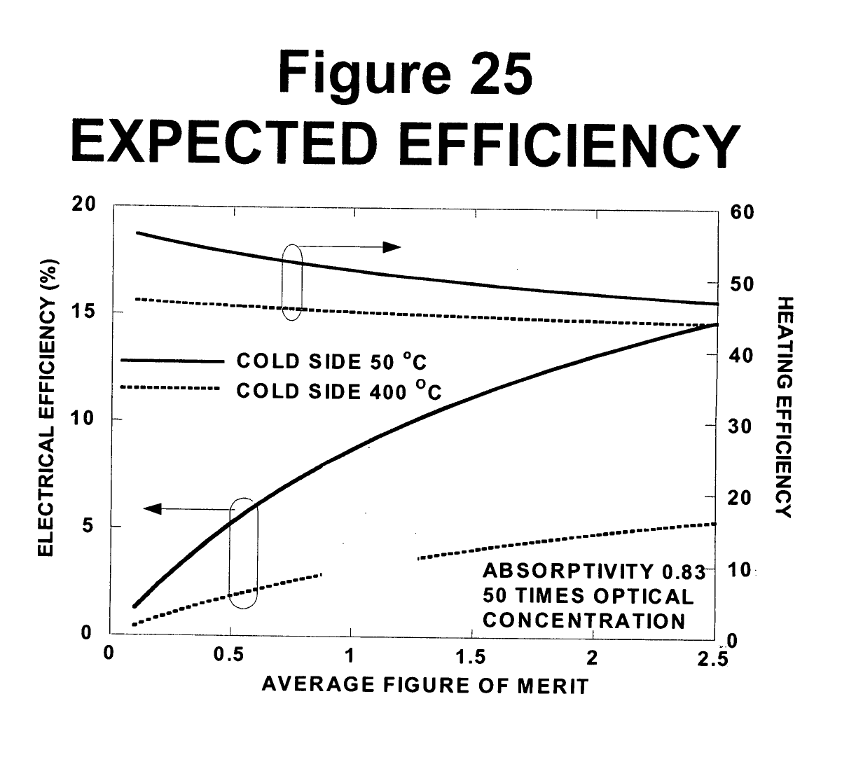

FIG. 24 shows examples of modeling results of the combined solar thermoelectric generator with hot water system for a system without optical concentration. The left vertical axis shows electrical generation efficiency and right vertical axis shows water heating efficiency. These efficiency values depend on the hot water temperature, and emissivity of the selective absorbers, in addition to other properties. With low (thermal) emissivity surfaces, higher efficiency can be reached. For example, for emissivity values of 0.03 and 0.05, electrical efficiency values of about 4 to about 6% and heating efficiency values of about 50 to about 60% may be achieved for ZT values of 1 to 1.5. FIG. 25 shows exampled of modeling results of combined solar thermoelectric generator with the cold side temperature varying from 50° C. to 400° C., similar to that experienced by fluids flowing in the pipes in trough solar thermal plant. For example, for cold side temperatures described above, the electrical efficiency values of about 3 to about 10% and heating efficiency values of about 45 to about 55% may be achieved for ZT values of 1 to 1.5. Depending on ZT values and other parameters, the thermoelectric generators can generate 3-10% additional electricity and the rest of heat can be used to drive mechanical-based power conversion cycles. It is understood that these are only examples, and for each applications, optimization of the system can be realized to realize maximum gain in efficiency and cost of electricity generation.

While the invention has been described in connection with the specific embodiments thereof, it will be understood that it is capable of further modification. Furthermore, this application is intended to cover any variations, uses, or adaptations of the invention, including such departures from the present disclosure as come within known or customary practice in the art to which the invention pertains, and as fall within the scope of the appended claims.

All publications, patents, and patent applications mentioned in this specification are herein incorporated by reference to the same extent as if each individual publication, patent, or patent application was specifically and individually indicated to be incorporated by reference.

The following references are incorporated herein by reference in their entirety:
1. N. Lewis et al., “Basic research Needs for solar Energy Utilization,” Department of Energy, Office of Science (2005).
2. M. Telkes, “Solar Thermoelectric Generators,” Journal of Applied Physics, 25, 765 (1954).
3. G. Chen and X. Y. Chen, “Solar to Electric Energy Conversion via Thermoelectric Devices,” Invited presentation, MRS Fall Meeting, Boston, 2006.
4. H. J. Goldsmid, Thermoelectric Refrigeration, Plenum Press, New York (1964).
5. A. F. loffe Semiconductor Thermoelements and Thermoelectric Cooling, Infosearch, London, (1957).
6. D. M. Rowe (editor), “CRC Handbook of Thermoelectrics,” CRC Press, Boca Raton, Fla., (1995).
7. T. Caillat, J.-P. Fleurial, G. J. Snyder, A. Zoltan, D. Zoltan, and A. Borshchevsky, “Development of a High Efficiency Thermoelectric Unicouple for Power Generation Applications,” in 18th international Conference on Thermoelectrics, p 473, IEEE, Piscataway, N.J. (1999).
8. Takenobu Kajikawa, “Thermoelectric Power Generation Systems Recovering Heat from Combustible Solid Waste in Japan,” in 15th International Conference on Thermoelectrics, p. 343, IEEE, Pasadena, Calif. (1996).
9. R. Venkatasubramanian, E. Siivola, T. Colpitts, and B. O'Quinn, “Thin-film Thermoelectric Devices with High Room-temperature Figures of Merit,” Nature, 413, 597 (2001).
10. T. C. Harman, P. J. Taylor, M. P. Walsh, and B. E. LaForge, “Quantum Dot Superlattice Thermoelectric Materials and Devices,” Science, 297, 2229 (2002).
11. M. S. Dresselhaus, G. Chen, M. Y. Tang, R. Yang, H. Lee, D. Z. Wang, Z. F. Ren, J. P. Fleurial, and P. Gogna, “New Directions for Thermoelectric Materials,” Advanced Materials, 19, 1-12 (2007).
12. G. Chen, M. S. Dresselhaus, J.-P. Fleurial, and T. Caillat, “Recent Developments in Thermoelectric Materials,” International Materials Review, 48, 45 (2003).
13. K. F. Hsu, S. Loo, F. Guo, W. Chen, J. S. Dyck, C. Uher, T. Hogan, E. K. Polychroniadis and M. G. Kanatzidis, “Cubic AgPb,SbTe2+,n: Bulk Thermoelectric Materials with High Figure of Merit,” Science, 303, 818 (2004).
14. T. Harman, M. P. Walsh, B. E. LaForge, and G. W. Turner, “Nanostructured Thermoelectrics Materials,” Journal of Electronic Materials, 34, L19 (2005).
15. R. C. Schubert and L. D. Ryan, “Fundamentals of Solar Heating,” Prentice-Hall, Englewood Cliffs, N.J., 1981.
16. J. Karni, A. Kribus, P. Doron, R. Rubin, A. Fiterman, and D. J. Sagie, “A High-pressure, High-temperature Solar Receiver,” Solar Energy Engineering-Transactions of the ASME, 119, 74 (1997).
17. R. Winston, J. C. Minano and P. G. Benitez, “Nonimaging Optics,” Academic Press (2004).
18. C. H. Henry, “Limiting Efficiencies of Ideal Single and Multiple Energy Gap Terrestrial Solar Cells,” Journal of Applied Physics, 51, 4494 (1980).
19. http://www.hi-z.com/index.html
20. H. J. Goldsmid, “Applications of Thermoelectricity,” London, New York, Methuen; Wiley, (1960).
21. T. M. Tritt and M. A. Subramanian (Guest editors), “Thermoelectric Materials and Applications,” MRS Bulletin, March (2006).
22. T. M. Tritt (Editor), “Recent Trend in Thermoelectric Materials Research: Semiconductor and Semimetals,” p 69, Academic Press, San Diego (2001).
23. L. D. Hicks and M. Dresselhaus, “Effect of Quantum-Well Structures on the Thermoelectric Figure of Merit,” Physical Review, B47, 12727, (1993).
24. http://www.randbenergy.com/presentation_english.htm#12
25. M. S. Dresselhaus, “Quantum Wells and Quantum Wires for Potential Thermoelectric Applications,” in “Recent Trend in Thermoelectric Materials Research: Semiconductor and Semimetals,” III 71, pl, Edited by T. Tritt, Academic Press, San Diego (2001).
26. G. Chen, “Phonon Heat Conduction in Low-Dimensional Structures”, in “Semiconductors and Semimetals,” 71, p 203, Edited by T. Tritt, Academic press, San Diego (2001).
27. G. Chen, “Nanoscale Energy Transfer and Conversion,” Oxford University Press, (2005).
28. http://www.sunselect.de/opencms/sites/alanod-sunselect.de/en/Produkte/sunselect/index.html
29. http://www.espressoinilkcooler.com/solar_hot_water_system_with_self_contained_perpetual_power_supply.htm
30. http://www.globalte.com
31. M. Telkes, “Solar Thermoelectric Generators,” Journal of Applied Physics, 25, 765 (1954).
32. E. Weston, U.S. Pat. No. 389,124 (1888), U.S. Pat. No. 389,125 (1888); H. F. Cottle, U.S. Pat. No. 608,755 (1898); J. S. Williams, British Patent No. 700 (1882) and 5109 (1883); A. R. Bennett, British Patent No. 18,672 (1911); M. L. Severy, U.S. Pat. Nos. 527,377 and 527,379 (1894); W. W. Colbentz, U.S. Pat. No. 1,077,219 (1913).
33. H. Naito, Y. Johsaka, D. Cooker, and H. Arashi, “Development of A Solar Receiver for a High-Efficiency Thermionic/Thermoelectric Conversion System,” Solar Energy, v. 58, pp. 191-195 (1996).
34. Y. V. Borobiev, J. Gonzalez-Hernandez, and A. Kribus, “Analysis of Potential Conversion Efficiency of a Solar Hybrid System with High-Temperature Stage,” ASME J. Sola Engineering, v. 128, pp. 258-260 (2006).
35. http://www.wbdg.org/design/swheating.php
36. M.-S. Jeng, R.G. Rang and G. Chen, “Monte Carlo Simulation of Thermoelectric Properties of Nanocomposites,” ICT05, June 19, Clemson, (2005).
37. R. G. Yang and G. Chen, “Thermoelectric Transport in Nanocomposites,” SAE Conference Paper, 2006-01-0289 (2006).
38. http://www.estif.org/fileadmin/downloads/press/Joint_PR_solar thermal_capacity.doc
39. Solar Heating Worldwide 2003, International Energy Association Solar Heating and Cooling Programme, May 2005.
40. Nanocomposites with High Thermoelectric Figures of Merit (U.S. application Ser. No. 10/977,363, filed Oct. 29, 2004).
41. Dismukes, J. P., Ekstrom, L., Steigmeier, E. F., Kudman, I. & Beers, D. S. Thermal and electrical properties of heavily doped Ge—Si alloys up to 1300K. J. Appl. Phys. 35, 2899-2907 (1964).
42. Vining, C. B., Laskow, W., Hanson, J. O., Beck, V. D. & Gorsuch, P. D. Thermoelectric properties of pressure-sintered Si_{0.8}Ge_{0.2} thermoelectric alloys. J. Appl. Phys. 69, 4333-4340 (1990).
43. Chen, G. Thermal conductivity and ballistic phonon transport in cross-plane direction of superlattices. Phys. Rev. B 57, 14958-15973 (1998).
44. Koga, T., Cronin, S. B., Dresselhaus, M. S., Liu, J. L. & Wang, K. L. Experimental proof-of-principle investigation of enhanced Z_{3D}T in (001) oriented Si/Ge superlattices. Appl. Phys. Lett. 77, 1490-1492 (2000).
45. Venkatasubramanian, R., Siivola, E., Colpitts, T. & O'Quinn, B. Thin-film thermoelectric devices with high room-temperature figures of merit. Nature 413, 597-602 (2001).
46. Harman, T. C., Taylor, P. J., Walsh, M. P. & Forge, B. E. Quantum dot superlattice thermoelectric materials and devices. Science 297, 2229-2232 (2002).
47. Woochul, K. et al. Thermal conductivity reduction and thermoelectric figure of merit increase by embedding nanoparticles in crystalline semiconductors. Phys. Rev. Lett. 96, 045901-045904 (2006).
48. Yang, R. G. & Chen, G. Thermal conductivity modeling of periodic two-dimensional nanocomposites. Phys. Rev. B 69, 195316-195325 (2004).
49. Dresselhaus, M. S. et al. New directions for low-dimensional thermoelectric materials. Adv. Mater, 19, 1043-1053 (2007).
50. Hsu, K. F. et al. Cubic AgPbₘSbTe₂₊ₘ: bulk thermoelectric materials with high figure of merit. Science 303, 818-821 (2004).
51. Fleurial, J. P., Caillat, T. & Borshchevsky, A. In proceedings of the 13th International Conference on Thermoelectrics 40-44 (AIP, New York, 1995).
52. Poudel, B. et al. High thermoelectric performance of nanostructured bismuth antimony telluride bulk alloys. Science 320, 634-638 (2008).
53. Rowe, D. M. (ed.) CRC Handbook of Thermoelectrics (CRC press, Boca Raton, 1995).
54. Ioffe, A. F. Physics of Semiconductors (Academic press Inc., New York, 1960).
55. Slack, G. A. & Hussain, M. A. The maximum possible conversion efficiency of silicon-germanium thermoelectric generators. J. Appl. Phys. 70, 2694-2718 (1991).
56. Vining, C. B. A model for high-temperature transport properties of heavily doped n-type silicon-germanium alloys. J. Appl. Phys. 69, 331-341 (1991).
57. Tritt, T. M. (ed.), Semiconductors and Semimetals (Academic Press, San Diego, 2001).
58. Abeles, B. Lattice thermal conductivity of disordered semiconductor alloys at high temperatures. Phys. Rev. 131, 1906-1911 (1963).
59. Abrikosov, N. K., Zemskov, V. S., Iordanishvili, E. K., Petrov, A. V. & Rozhdestvenskaya, V. V. Thermoelectric properties of silicon-germanium-boron alloys. Sov. Phys. Semicond. 2, 1762-1768 (1968).
60. Rowe, D. M., Shukla, V. S. & Savvides, N. Phonon scattering at grain boundaries in heavily doped fine-grained silicon-germanium alloys. Nature 290, 765-766 (1981).
61. Methods for High Figure of Merit in Nanostructured Thermoelectric Materials (U.S. Application No. 60/872,242, filed Dec. 1, 2006).
62. Solar Thermoelectric Converters (U.S. Application No. 60/858,515, filed Nov. 8, 2006).

What is claimed is:

1. An energy generation method, comprising:
receiving solar radiation at a solar absorber;
providing heat from the solar absorber to a hot side of a set of thermoelectric converters;
generating electricity from the set of thermoelectric converters; and
providing heat from a cold side of the set of thermoelectric converters to a fluid being provided into a solar fluid heating system or a solar thermal to electrical conversion plant.

2. The method of claim 1, wherein the fluid comprises water being provided into a solar hot water heating system.

3. The method of claim 2, wherein the heated water is provided into a building.

4. The method of claim 1, wherein the fluid is provided into at least one of a Rankine or Stirling solar thermal to electrical conversion plant.

5. The method of claim 4, wherein the fluid is circulated through a conduit.

6. The method of claim 5, wherein the conduit is physically and thermally isolated from the solar absorber by the set of thermoelectric converters.

7. The method of claim 5, wherein the step of circulating comprises one of: pumping, siphoning, diffusing, and combinations thereof; and the fluid comprises water, liquid salt or oil.

8. The method of claim 4, wherein the fluid comprises a gas and the solar thermal to electrical conversion plant comprises a Stirling plant.

9. The method of claim 5, further comprising generating electricity using the solar thermal plant.

10. The method of claim 1, further comprising concentrating the solar radiation to the solar absorber.

11. A system, comprising:
at least one thermoelectric device; and
a solar fluid heating system or a solar thermal to electrical conversion plant.

12. The system of claim 11, wherein the system comprises the solar fluid heating system, and the at least one thermoelectric device and the solar fluid heating system are thermally and physically integrated.

13. The system of claim 11, wherein the system comprises the solar thermal to electrical conversion plant and the solar thermal to electrical conversion plant heats a fluid and utilizes the heated fluid to generate electricity.

14. The system of claim 13, wherein the at least one thermoelectric device and the solar thermal to electrical conversion plant are thermally and physically integrated.

15. The system of claim 14, wherein solar thermal plant to electrical conversion comprises a Rankine or Stirling solar thermal plant.

16. The system of claim 11, further comprising a solar absorber which is thermally and physically integrated with the set of thermoelectric converters.

17. The system of claim 16, wherein the solar fluid heating system or the solar thermal to electrical conversion plant comprise a fluid conduit which is physically and thermally isolated from the solar absorber by a set of thermoelectric converters of the thermoelectric device.

18. The system of claim 16, further comprising an optical solar concentrator which is adapted to concentrate solar radiation onto the solar absorber.

19. The system of claim 17, wherein the set of thermoelectric converters comprise thermoelectric legs comprising compacted nanoparticles.
